(19) United States
(12) Patent Application Publication
(10) Pub. No.: US 2026/0033181 A1
(43) Pub. Date: Jan. 29, 2026

(54) Array Substrate, Display Panel and Display Device

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Tiaomei Zhang, Beijing (CN); Ziyang Yu, Beijing (CN); Pan Zhao, Beijing (CN); Erjin Zhao, Beijing (CN); Mengqi Wang, Beijing (CN); Jianpeng Wu, Beijing (CN); Zhiliang Jiang, Beijing (CN); Ming Hu, Beijing (CN)

(21) Appl. No.: 18/996,544

(22) PCT Filed: Apr. 17, 2024
(86) PCT No.: PCT/CN2024/088421

§ 371 Date: Jan. 17, 2025

(30) Foreign Application Priority Data
May 30, 2023 (CN) 202310629298.1

(51) Int. Cl. H10K 59/131

(52) U.S. Cl. CPC H10K 59/131

(57) ABSTRACT

An array substrate includes a substrate, a plurality of pixel circuits, a first wiring layer, a bridge line layer and a second wiring layer. The first wiring layer includes first to third initialization signal lines. Each row of pixel circuits is electrically connected to a first initialization signal line, a second initialization signal line and a third initialization signal line. The bridge line layer includes of columns of transfer blocks and first fanout lines. The second wiring layer includes connecting lines, data lines and second fanout lines. Each connecting line is electrically connected to one of the first to third initialization signal lines by a column of transfer blocks. The data lines include first data lines located in a display area, an end of each second fanout line extends to a fanout area; and a first fanout line is electrically connected to a first data line and a second fanout line.

### CROSS-REFERENCE TO RELATED APPLICATIONS

This application is the United States national phase of International Patent Application No. PCT/CN2024/088421, filed Apr. 17, 2024, and claims priority to Chinese Patent Application No. 202310629298.1, filed May 30, 2023, the disclosures of which are hereby incorporated by reference in their entireties.

### BACKGROUND OF THE INVENTION

### FIELD OF THE INVENTION

The present disclosure relates to the field of display technologies, and in particular, to an array substrate, a display panel and a display device.

### DESCRIPTION OF RELATED ART

Organic light-emitting diode (OLED) display devices have gradually become one of mainstream products in the display field due to self-luminescence, no need for backlight, high contrast, thin thickness, wide viewing angle, fast response speed, being capable of being used for flexible panels, wide usage temperature range, simple structure and process, and other excellent performance. OLED display panels may be widely used in terminal products such as smart phones, tablet computers, televisions and wearable devices (such as watches). High pixel density (pixels per inch, PPI) and narrow frame are currently an important development direction of the OLED display devices.

### SUMMARY OF THE INVENTION

In an aspect, an array substrate is provided. The array substrate has a display area and a fanout area, and the fanout area is adjacent to a side edge of the display area. The array substrate includes a substrate, a plurality of pixel circuits, a first wiring layer, a bridge line layer and a second wiring layer. The plurality of pixel circuits are disposed on the substrate, and the plurality of pixel circuits are arranged in a plurality of rows and a plurality of columns. The first wiring layer is disposed on a side of the plurality of pixel circuits away from the substrate and includes a plurality of first initialization signal lines, a plurality of second initialization signal lines and a plurality of third initialization signal lines extending in a first direction. The first direction is a row direction in which the plurality of pixel circuits are arranged. Each row of pixel circuits is electrically connected to a first initialization signal line, a second initialization signal line and a third initialization signal line. The bridge line layer is disposed on a side of the first wiring layer away from the substrate and includes a plurality of columns of transfer blocks and a plurality of first fanout lines. Each column of transfer blocks includes multiple transfer blocks disposed at intervals in a second direction, the plurality of first fanout lines extend in the first direction, and the second direction is a column direction in which the plurality of pixel circuits are arranged. The second wiring layer is disposed on a side of the bridge line layer away from the substrate and includes a plurality of connecting lines, a plurality of data lines and a plurality of second fanout lines extending in the second direction. Each connecting line is electrically connected to one of the plurality of first initialization signal lines, the plurality of second initialization signal lines and the plurality of third initialization signal lines by a column of transfer blocks. Each data line is electrically connected to a column of pixel circuits. The plurality of data lines include a plurality of first data lines, and ends of the first data lines proximate to the fanout area are located in the display area. Ends of the second fanout lines proximate to the fanout area extend to the fanout area. A first fanout line is electrically connected to a first data line and a second fanout line.

In some embodiments, two ends of at least one transfer block in the first direction are both electrically connected to the first initialization signal line, the second initialization signal line or the third initialization signal line.

In some embodiments, the at least one transfer block is disposed symmetrically about a connecting line electrically connected to the transfer block. The transfer block includes a first sub-portion, a second sub-portion and third sub-portions. An orthographic projection of the first sub-portion on the substrate partially overlaps with an orthographic projection of the connecting line on the substrate; and the first sub-portion is electrically connected to the connecting line. The second sub-portion extends in the first direction, is connected to the first sub-portion, and is disposed symmetrically about a midline of the first sub-portion in the first direction. Third sub-portions are each connected to an end of the second sub-portion away from the first sub-portion. In the second direction, a dimension of the third sub-portion is greater than a dimension of the second sub-portion; and the third sub-portions are electrically connected to the first initialization signal line, the second initialization signal line or the third initialization signal line.

In some embodiments, a plurality of transfer blocks arranged into the plurality of columns of transfer blocks include a plurality of columns of first transfer blocks, a plurality of columns of second transfer blocks and a plurality of columns of third transfer blocks disposed at intervals in the first direction. Each column of first transfer blocks includes multiple first transfer blocks disposed at intervals in the second direction, and multiple first transfer blocks in a column are respectively electrically connected to the plurality of first initialization signal lines. Each column of second transfer blocks includes multiple second transfer blocks disposed at intervals in the second direction, and multiple second transfer blocks in a column are respectively electrically connected to the plurality of second initialization signal lines. Each column of third transfer blocks includes multiple third transfer blocks disposed at intervals in the second direction, and multiple third transfer blocks in a column are respectively electrically connected to the plurality of third initialization signal lines. The plurality of connecting lines include a plurality of first connecting lines, a plurality of second connecting lines and a plurality of third connecting lines. A first connecting line is electrically connected to a column of first transfer blocks, a second connecting line is electrically connected to a column of second transfer blocks, and a third connecting line is electrically connected to a column of third transfer blocks.

In some embodiments, in the first direction, a dimension of a first transfer block is greater than a dimension of a second transfer block, and the dimension of the second transfer block is greater than a dimension of a third transfer block.

In some embodiments, in the first direction, a first transfer block, a second transfer block and a third transfer block, as a whole, are arranged repeatedly, and a first connecting line, a second connecting line and a third connecting line, as a whole, are arranged repeatedly.

In some embodiments, the array substrate further includes a first source-drain conductive layer. The first source-drain conductive layer is disposed between the first wiring layer and the bridge line layer and includes a plurality of first connection patterns, a plurality of second connection patterns and a plurality of third connection patterns.

A first connection pattern includes a first sub-pattern and a second sub-pattern; the first sub-pattern is electrically connected to a first initialization signal line and a pixel circuit, and the second sub-pattern is electrically connected to a first transfer block. A second connection pattern includes a third sub-pattern and a fourth sub-pattern; the third sub-pattern is electrically connected to a second initialization signal line and a pixel circuit, and the fourth sub-pattern is electrically connected to a second transfer block. A third connection pattern includes a fifth sub-pattern and a sixth sub-pattern; the fifth sub-pattern is electrically connected to a third initialization signal line and a pixel circuit, and the sixth sub-pattern is electrically connected to a third transfer block.

In some embodiments, the first source-drain conductive layer further includes a fourth connection pattern, a fifth connection pattern and a sixth connection pattern. A shape and a size of the fourth connection pattern are respectively same as a shape and a size of the first sub-pattern, and the fourth connection pattern is electrically connected to the first initialization signal line and a pixel circuit. A shape and a size of the fifth connection pattern are respectively same as a shape and a size of the third sub-pattern, and the fifth connection pattern is electrically connected to the second initialization signal line and a pixel circuit. A shape and a size of the sixth connection pattern are respectively same as a shape and a size of the fifth sub-pattern, and the sixth connection pattern is electrically connected to the third initialization signal line and a pixel circuit.

In some embodiments, the second fanout line includes a first opening, and the first opening divides the second fanout line into a first routing segment and a second routing segment. An end of the first routing segment extends to the fanout area, and another end of the first routing segment extends to the first fanout line and is electrically connected to the first fanout line. The second routing segment is located on a side of the first routing segment away from the fanout area, and is electrically insulated from the first routing segment.

In some embodiments, the second fanout line further includes a plurality of first widened portions and a plurality of first extended portions that are disposed alternately in the second direction. The first widened portions and the first fanout lines are disposed in a staggered manner in the second direction. The bridge line layer further includes a first connection segment, an end of the first connection segment is connected to the first fanout line, and another end of the first connection segment is electrically connected to a first widened portion of the first routing segment closest to the first fanout line.

In some embodiments, the connecting line includes a plurality of second widened portions and a plurality of second extending portions that are disposed alternately in the second direction. In the first direction, a dimension of a second widened portion is greater than a dimension of a second extending portion, and the second widened portion is electrically connected to a transfer block.

In some embodiments, the first fanout line includes a second opening and a third opening. The second opening is located on a side of the first connection segment away from the first data line electrically connected to the first fanout line, and an orthogonal projection of the second opening on the substrate partially overlaps with an orthographic projection of a data line on the substrate. The third opening is located on a side of the first data line electrically connected to the first fanout line away from the second fanout line electrically connected to the first fanout line, and an orthogonal projection of the third opening on the substrate partially overlaps with an orthographic projection of a connecting line on the substrate.

In some embodiments, the bridge line layer further includes a plurality of columns of receiving patterns and a second connection segment. The plurality of columns of receiving patterns each include multiple receiving patterns disposed at intervals in the second direction, multiple receiving patterns in a column are respectively electrically connected to multiple pixel circuits in a column, and the multiple receiving patterns in the column are further electrically connected to a data line. An end of the second connection segment is electrically connected to the first fanout line, and another end of the second connection segment is electrically connected to a target receiving pattern. The target receiving pattern is a receiving pattern located on a side of the first fanout line proximate to the fanout area and closest to the first fanout line.

In some embodiments, in the second direction, the multiple receiving patterns and the multiple transfer blocks are disposed in a staggered manner, and at least one transfer block is located between the first fanout line and the target receiving pattern.

In some embodiments, the plurality of first data lines include at least one first data sub-line, an orthographic projection of the first data sub-line on the substrate does not overlap with an orthographic projection of a transfer block on the substrate. An orthographic projection of the second connection segment electrically connected to the first data sub-line on the substrate is located within the orthographic projection of the first data sub-line on the substrate.

In some embodiments, the plurality of first data lines include at least one second data sub-line, and an orthographic projection of the second data sub-line on the substrate partially overlaps with an orthographic projection of the column of transfer blocks on the substrate. The column of transfer blocks electrically connected to the second data sub-line includes a target transfer block, and the target transfer block is located on a side of the first fanout line proximate to the fanout area and closest to the first fanout line. An orthographic projection of the target transfer block on the substrate does not overlap with the orthographic projection of the second data sub-line on the substrate. The second connection segment electrically connected to the second data sub-line is a target connection segment. An orthographic projection of the target connection segment on the substrate is located within the orthographic projection of the second data sub-line on the substrate, and the target connection segment extends in the second direction and is spaced apart from the target transfer block. And/or, the target connection segment is a broken line, the orthographic projection of the target connection segment on the substrate does not at least partially overlap with the orthographic projection of the second data sub-line on the substrate, and the target connection segment and the target transfer block have a gap therebetween.

In some embodiments, two adjacent columns of pixel circuits are disposed symmetrically. The plurality of data lines are divided into a plurality of groups of data lines, each group of data lines includes two data lines, the two data lines in the group of data lines have a first interval therebetween, two adjacent groups of data lines have a second interval therebetween, and the first interval is less than the second interval. Each connecting line is located between two data lines in a group of data lines, and the two data lines in the group of data lines are disposed symmetrically about the connecting line. Each second fanout line is located between two data lines in a group of data lines, and the two data lines in the group of data lines are disposed symmetrically about the second fanout line.

In some embodiments, 1 to 10 connecting lines are included between two adjacent second fanout lines.

In some embodiments, the plurality of connecting lines include a plurality of first connecting lines, a plurality of second connecting lines and a plurality of third connecting lines, and a first connecting line, a second connecting line and a third connecting line are included in two adjacent second fanout lines. In the first direction and in a direction from an edge of the display area to another edge thereof, the second connecting line, the third connecting line and the first connecting line are disposed in sequence between two adjacent second fanout lines. Alternatively, in the first direction and in a direction from an edge of the display area to another edge thereof, the second connecting line, the first connecting line and the third connecting line are disposed in sequence between two adjacent second fanout lines. Alternatively, in the first direction and in a direction from an edge of the display area to another edge thereof, the first connecting line, the second connecting line and the third connecting line are disposed in sequence between two adjacent second fanout lines. Alternatively, in the first direction and in a direction from an edge of the display area to another edge thereof, the first connecting line, the third connecting line and the second connecting line are disposed in sequence between two adjacent second fanout lines. Alternatively, in the first direction and in a direction from an edge of the display area to another edge thereof, the third connecting line, the second connecting line and the first connecting line are disposed in sequence between two adjacent second fanout lines. Alternatively, in the first direction and in a direction from an edge of the display area to another edge thereof, the third connecting line, the first connecting line and the second connecting line are disposed in sequence between two adjacent second fanout lines.

In some embodiments, the second wiring layer further includes a plurality of first voltage signal lines disposed at intervals in the first direction, each first voltage signal line extends in the second direction; and a group of data lines is included between two adjacent first voltage signal lines. The bridge line layer further includes a plurality of first signal transfer lines disposed at intervals in the second direction, and each first signal transfer line extends in the first direction and is electrically connected to a row of pixel circuits. Each first voltage signal line is electrically connected to the plurality of first voltage signal transfer lines.

In another aspect, a display panel is provided. The display panel includes a plurality of light-emitting devices and the array substrate as described in any of the above embodiments. The plurality of light-emitting devices are located on a side of the array substrate, and a light-emitting device is electrically connected to a pixel circuit.

In yet another aspect, a display device is provided. The display device includes the display panel as described above and a driving circuit board. The driving circuit board is electrically connected to the fanout area of the array substrate of the display panel and configured to transmit a control signal to the array substrate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product and an actual timing of a signal to which the embodiments of the present disclosure relate.

FIG. 1 is a structural diagram of a display device, in accordance with some embodiments;

FIG. 2 is a structural diagram of another display device, in accordance with some embodiments;

FIG. 3 is a sectional view showing a structure of a display panel, in accordance with some embodiments;

FIG. 4 is a structural diagram of a pixel circuit, in accordance with some embodiments;

FIG. 5 is a structural diagram of a first semiconductor layer to a first wiring layer, in accordance with some embodiments;

FIG. 6 is a structural diagram of a first semiconductor layer to a first source-drain conductive layer, in accordance with some embodiments;

FIG. 7 is an equivalent circuit diagram of a pixel circuit, in accordance with some embodiments;

FIG. 8 is a structural diagram of a first semiconductor layer to a second source-drain conductive layer, in accordance with some embodiments;

FIG. 9 is a structural diagram of a first semiconductor layer to a third source-drain conductive layer, in accordance with some embodiments;

FIG. 10 is a structural diagram of a bridge line layer and a third source-drain conductive layer, in accordance with some embodiments;

FIG. 11 is a structural diagram of an array substrate, in accordance with some embodiments;

FIG. 12 is a structural diagram of a first semiconductor layer, a first wiring layer and a first source-drain conductive layer, in accordance with some embodiments;

FIG. 13 is a structural diagram of a first source-drain conductive layer and a second source-drain conductive layer, in accordance with some embodiments;

FIG. 14 is a structural diagram of a bridge line layer and a third source-drain conductive layer, in accordance with some embodiments;

FIG. 15 is a structural diagram of a bridge line layer, in accordance with some embodiments;

FIG. 16 is a structural diagram of a bridge line layer and a second wiring layer, in accordance with some embodiments;

FIG. 17 is a structural diagram of another bridge line layer, in accordance with some embodiments;

FIG. 18 is a structural diagram of another bridge line layer and another second wiring layer, in accordance with some embodiments;

FIG. 19 is a structural diagram of yet another bridge line layer, in accordance with some embodiments;

FIG. 20 is a structural diagram of yet another bridge line layer and yet another second wiring layer, in accordance with some embodiments;

FIG. 21 is a structural diagram of yet another bridge line layer, in accordance with some embodiments;

FIG. 22 is a structural diagram of yet another bridge line layer and yet another second wiring layer, in accordance with some embodiments;

FIG. 23 is a structural diagram of yet another bridge line layer, in accordance with some embodiments;

FIG. 24 is a structural diagram of yet another bridge line layer and yet another second wiring layer, in accordance with some embodiments; and

FIG. 25 is an enlarged partial view of a region C in FIG. 11.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact.

The phrase “at least one of A, B and C” has a same meaning as the phrase “at least one of A, B or C”, and they both include the following combinations of A, B and C:

only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°, and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

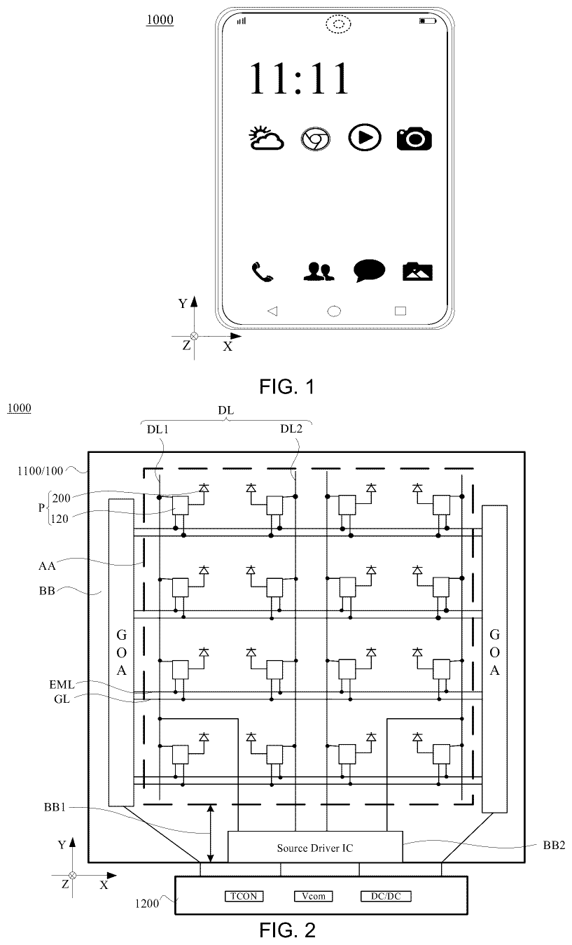

Referring to FIG. 1, some embodiments of the present disclosure provide a display device 1000, and the display device 1000 may be any device that displays images whether in motion (such as a video) or fixed (such as a still image), and regardless of text or image.

For example, the display device 1000 may be any product or component having a display function, such as a television, a notebook computer, a tablet computer, a mobile phone, a personal digital assistant (PDA), a navigator, a wearable device, an augmented reality (AR) device, a virtual reality (VR) device, a vehicle display, and a flight display. For example, as shown in FIG. 1, the display device 1000 may be a mobile phone.

In terms of the light emission type of the display device 1000, the display device 1000 may be an organic light-emitting diode display device, a quantum dot electroluminescent (quantum dot light-emitting diode, QLED) display device, a tiny light-emitting diode (mini/micro light emitting display, MLED) display device, or the like. In terms of the form of the display device 1000, the display device 1000 may be a flat display device, a curved display device, a foldable display device, or the like. In terms of the shape of the display device 1000, the display device 1000 may be in a rectangular or circular shape. Specific limitations are not made in the embodiments of the present disclosure. Some embodiments of the present disclosure are exemplarily described below by considering an example of a rectangular and flat organic light-emitting diode display device, but the embodiments of the present disclosure are not limited thereto, and any other display devices may also be considered as long as the same technical concept is applied.

In some embodiments, referring to FIG. 2, the display device 1000 includes a display panel 1100 and a driving circuit board 1200. The driving circuit board 1200 may include, for example, a timing controller (TCON), a power management chip DC/DC, an adjustable resistor divider circuit (for generating Vcom), and other driving circuits. The driving circuit board 1200 may further include other circuit structures, which are not listed here one by one. The driving circuit board is electrically connected to the display panel 1100, and is used to transmit a control signal to the display panel 1100, so as to drive the display panel 1100 to realize image display. In addition, the display device 1000 may further include an under-screen camera, an under-screen fingerprint recognition sensor, and the like, so that the display device 1000 is able to achieve various functions such as taking pictures, video recording, fingerprint recognition or face recognition.

Referring to FIG. 2, the display panel 1100 has a display area AA and a peripheral area BB, and the peripheral area BB is located on at least one side of the display area AA. For example, the peripheral area BB is disposed around the display area AA. The display area AA is an area of the display panel 1100 for displaying images. The display area AA is provided with a plurality of sub-pixels P therein. The sub-pixel P is the minimum light-emitting unit of the display panel 1100 and the sub-pixel P is used to display images.

The plurality of sub-pixels P may emit light of the same color, such as white light or blue light. The display panel further includes a color film layer disposed on a display side, that is, the display panel adopts a COE (color filter layer on encapsulation, CF on Encapsulation) structure. Alternatively, the plurality of sub-pixels P may emit light of different colors. For example, the plurality of sub-pixels P include a red sub-pixel for emitting red light, a green sub-pixel for emitting green light, and a blue sub-pixel for emitting blue light.

With continued reference to FIG. 2, the peripheral area BB may be used, for example, to provide with gate driving circuits (e.g., gate on arrays, GOAs), control signal lines (e.g., clock signal lines and power supply voltage signal lines) and a bonding driver chip (e.g., a source driver chip, a source driver integrated circuit (IC)). The functions of the peripheral area BB are not limited thereto, and details are not listed one by one in the embodiments of the present disclosure.

The peripheral area BB includes a fanout area BB1 located on a side of the display area, that is, the fanout area BB1 is an area of the peripheral area BB located on a side of the display area AA. The fanout area BB1 may be used to lead out the signal lines of the peripheral area and bond the signal lines to the driving circuit board or the driver chip. The fanout area BB1 is adjacent to a side edge of the display area AA. For example, the fanout area BB1 is adjacent to a lower side edge of the display area AA.

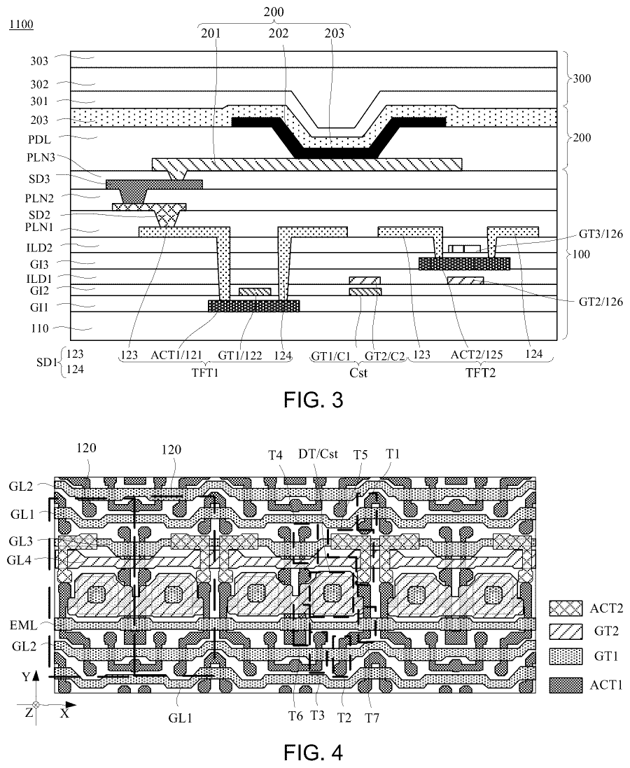

Referring to FIG. 3, the display panel 1100 includes an array substrate 100, a plurality of light-emitting devices 200 and an encapsulation layer 300 that are stacked. The display panel 1100 may further include functional stack layer(s) disposed on a side of the encapsulation layer 300 away from the array substrate. The functional stack layer(s) may be, for example, one or more of a touch function layer, an anti-reflection layer, a hardening layer, a color film layer (the display panel adopts the COE structure) and an anti-fingerprint layer, so that the display panel may achieve corresponding function(s). The embodiments of the present disclosure do not specifically limit types and quantities of the above functional stack layer(s).

With continued reference to FIG. 3, the light-emitting device 200 may include, for example, an anode 201, a light-emitting functional layer 202 and a cathode layer 203 that are stacked. The display panel 1100 may further include a pixel defining layer PDL. The pixel defining layer PDL is disposed on a side of the anode 201 away from the array substrate 100 and includes a plurality of openings, and each light-emitting device 200 is located in an opening.

The encapsulation layer 300 is configured to reduce a risk of moisture and oxygen in the external environment entering the light-emitting device 200, thereby increasing a service life of the display panel 1100. The encapsulation layer 300 may be encapsulation films or an encapsulation substrate. For example, as shown in FIG. 3, the encapsulation layer 300 may be encapsulation films. In this case, the encapsulation layer 300 may include a first inorganic encapsulation layer 301, an organic encapsulation layer 302 and a second inorganic encapsulation layer 303 that are stacked sequentially.

The array substrate 100 has a display area AA and a fanout area BB1. The display area AA of the array substrate 100 and the display area AA of the display panel 1100 are the same area, and the fanout area BB1 of the array substrate 100 and the fanout area BB1 of the display panel 1100 are the same area. That is, the array substrate 100 has the display area AA and the fanout area BB1 adjacent to a side edge of the display area AA.

Referring to FIG. 2, the array substrate 100 includes a plurality of pixel circuits 120. The plurality of pixel circuits 120 are arranged in a plurality of rows and a plurality of columns. Each row of pixel circuits 120 includes multiple pixel circuits 120 arranged at intervals in a first direction X, and the plurality of rows of pixel circuits 120 are arranged in a second direction Y. Each column of pixel circuits 120 includes multiple pixel circuits 120 arranged in the second direction Y, and the plurality of columns of pixel circuits 120 are arranged in the first direction X. That is, the first direction X is a row direction in which the plurality of pixel circuits 120 are arranged, and the second direction Y is a column direction in which the plurality of pixel circuits 120 are arranged. The first direction X and the second direction Y intersect with each other. For example, the first direction X and the second direction Y are perpendicular to each other.

Referring to FIG. 3, the array substrate 100 further includes a substrate 110, and the plurality of pixel circuits are disposed on the substrate 110. The substrate 110 may be a rigid substrate, and a material of the rigid substrate includes, for example, glass. Alternatively, the substrate 110 may be a flexible substrate, and a material of the flexible substrate includes, for example, any of polyimide (PI), polycarbonate (PC) or polyvinyl chloride (PVC).

As shown in FIG. 3, the array substrate 100 further includes a first semiconductor layer ACT1, a first gate insulation layer GI1, a first gate conductive layer GT1, a second gate insulation layer GI2, a second gate conductive layer GT2, a first interlayer dielectric layer ILD1, a second semiconductor layer ACT2, a third gate insulation layer GI3, a third gate conductive layer GT3, a second interlayer dielectric layer ILD2, a first source-drain conductive layer SD1, a first planarization layer PLN1, a second source-drain conductive layer SD2, a second planarization layer PLN2, a third source-drain conductive layer SD3 and a third planarization layer PLN4 which are provided in sequence in a direction perpendicular to the substrate 110 and from the substrate 110 to the light-emitting device 200.

The pixel circuit 120 includes a plurality of thin film transistors (TFTs) and at least one capacitor Cst. For example, the pixel circuit 120 may be a “3T1C” circuit, a “7T1C” circuit or an “8T1C” circuit, where “T” refers to the TFT, and the number before “T” refers to the number of the TFTs, “C” refers to the capacitor Cst, and the number before “C” refers to the number of the capacitors Cst. The following embodiments of the present disclosure will be exemplarily described by considering an example where the pixel circuit 120 is an “8T1C” circuit, but implementations of the present disclosure are not limited thereto, and any other pixel circuits 120 may also be considered as long as the same technical concept is applied.

As shown in FIG. 3, the thin film transistors may include a first thin film transistor TFT1 and a second thin film transistor TFT2. The first thin film transistor TFT1 may include a first active layer 121 disposed in the first semiconductor layer ACT1, a gate 122 disposed in the first gate conductive layer GT1, and a source 123 and a drain 124 that are disposed in the first source-drain conductive layer SD1. The second thin film transistor TFT2 may include a second active layer 125 disposed in the second semiconductor layer ACT2, gates 126 disposed in the second gate conductive layer GT2 and the third gate conductive layer GT3, and a source 123 and a drain 124 that are disposed in the first source-drain conductive layer SD1. The source 123 and the drain 124 may be symmetrical in structure, and thus the source 123 and the drain 124 may be exchanged.

For example, the first thin film transistor TFT1 may be a low-temperature polysilicon thin film transistor, that is, the first semiconductor layer ACT1 is made of low-temperature polysilicon. The second thin film transistor TFT2 may be an oxide thin film transistor, that is, the second semiconductor layer ACT2 is made of metal oxide, such as indium gallium zinc oxide or indium gallium tin oxide.

Based on advantages of low-temperature polysilicon thin film transistors such as high mobility and fast charging and advantages of oxide thin film transistors such as low leakage current, the low-temperature polysilicon thin film transistors and the oxide thin film transistors are integrated into the array substrate 100, that is, the pixel circuit 120 includes the low-temperature polysilicon thin film transistor and the oxide transistor. By utilizing the advantages of both the low-temperature polysilicon thin film transistor and the oxide transistor, a power consumption of the array substrate 100 may be reduced and a display quality of the display panel 1100 may be improved.

Referring to FIG. 4, the array substrate 100 further includes a plurality of scan signal lines GL and a plurality of light emission control signal lines EML. For example, the plurality of scan signal lines GL include a plurality of first scan signal lines GL1, a plurality of second scan signal lines GL2, a plurality of third scan signal lines GL3 and a plurality of fourth scan signal lines GL4. A row of pixel circuits 120 is electrically connected to a first scan signal line GL1, a second scan signal line GL2, a third scan signal line GL3, a fourth scan signal line GL4 and a light emission control signal line EML. The first scan signal line GL1, the second scan signal line GL2, the third scan signal line GL3 and the light emission control signal line EML are located in the first gate conductive layer GT1, and the fourth scan signal line GL4 is located in the second gate conductive layer GT2.

It can be understood that the first gate conductive layer GT1 may include the gate of the first thin film transistor TFT1, the first scan signal line GL1, the second scan signal line GL2, the third scan signal line GL3, the light emission control signal line EML and other structures. The gate of the first thin film transistor TFT1 constitutes a portion of the pixel circuit 120. The pixel circuit 120 includes a structure located in the first gate conductive layer GT1, and the first gate conductive layer GT1 does not completely belong to the pixel circuit 120. Similarly, the pixel circuit 120 includes a structure located in the second gate conductive layer GT2, and the second gate conductive layer GT2 does not completely belong to the pixel circuit 120.

In some embodiments, with continued reference to FIG. 4, the pixel circuit 120 includes a driving transistor DT, a first transistor T1, a second transistor T2, a third transistor T3, a fourth transistor T4, a fifth transistor T5, a sixth transistor T6, a seventh transistor T7 and a capacitor Cst. The transistors (the driving transistor DT and the first to seventh transistors) each include a gate, a first electrode and a second electrode. The first electrode is one of a source and a drain of a transistor, and a second electrode is the other of the source and the drain of the transistor. For example, the first electrode is the source of the transistor, and the second electrode is the drain of the transistor.

The first scan signal line GL1 forms a gate of the first transistor T1, the second scan signal line GL2 forms gates of the second transistor T2 and the third transistor T3, the third scan signal line GL3 forms a gate of the fourth transistor T4, the fourth scan signal line GL4 forms a gate of the fifth transistor T5, and the light emission control signal line EML forms gates of the sixth transistor T6 and the seventh transistor T7.

In the embodiments of the present disclosure, a first wiring layer, a bridge line layer and a second wiring layer are further included. The first wiring layer is disposed on a side of the plurality of pixel circuits 120 away from the substrate 110, the bridge line layer is disposed on a side of the first wiring layer away from the substrate, and the second wiring layer is disposed on a side of the bridge line layer away from the substrate. For example, the first wiring layer may be provided in the same layer as the third gate conductive layer GT3, the bridge line layer may be provided in the same layer as the second source-drain conductive layer SD2, and the second wiring layer may be provided in the same layer as the third source-drain conductive layer SD3. This is beneficial to reducing the number of film layers in the array substrate 100 and reducing the production cost of the array substrate 100.

It can be understood that in some other embodiments, the first wiring layer and the third gate conductive layer GT3 may be two separate film layers. For example, the first wiring layer may be provided between the third gate conductive layer GT3 and the first source-drain conductive layer SD1. Similarly, the bridge line layer and the second source-drain conductive layer SD2 may be two separate film layers, and the second wiring layer and the third source-drain conductive layer SD3 may be two separate film layers. All the following embodiments of the present disclosure will be exemplarily described by considering an example where “the first wiring layer and the third gate conductive layer GT3 are provided in the same layer, the bridge line layer and the second source-drain conductive layer SD2 are provided in the same layer, and the second wiring layer and the third source-drain conductive layer SD3 are provided in the same layer”. In this way, the first wiring layer and the third gate conductive layer GT3 are the same film layer, the bridge line layer and the second source-drain conductive layer SD2 are the same film layer, and the second wiring layer and the third source-drain conductive layer SD3 are the same film layer. Based on this, the first wiring layer adopts the same mark “GT3” as the third gate conductive layer GT3, the bridge line layer adopts the same mark “SD2” as the second source-drain conductive layer SD2, and the second wiring layer adopts the same mark “SD3” as the third source-drain conductive layer SD3.

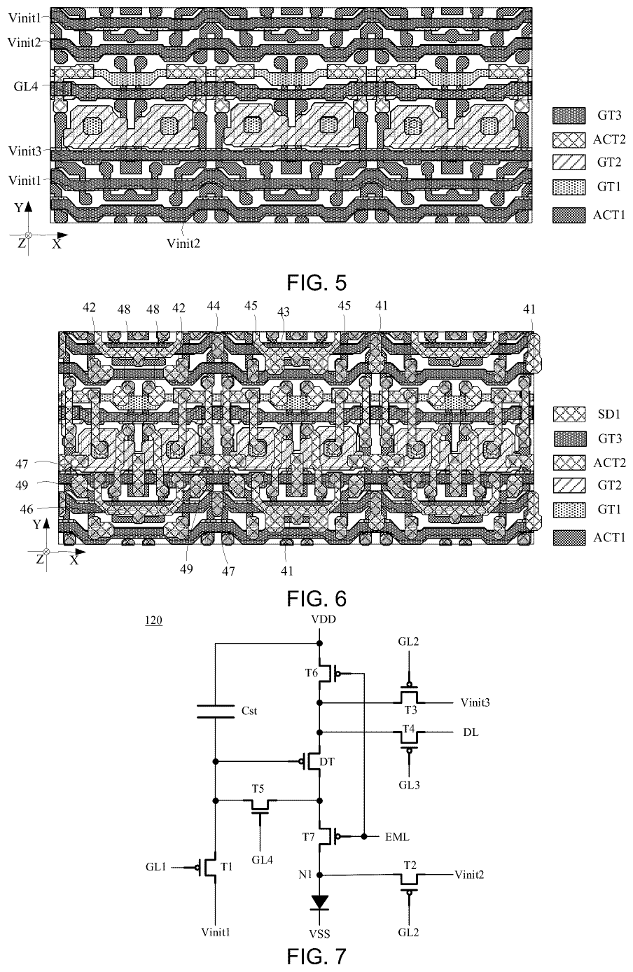

FIG. 5 is a structural diagram of the array substrate 100 with a first wiring layer GT3 added based on FIG. 4. Referring to FIG. 5, the first wiring layer GT3 includes a plurality of first initialization signal lines Vinit1, a plurality of second initialization signal lines Vinit2 and a plurality of third initialization signal lines Vinit3 extending in the first direction X. FIG. 5 exemplarily shows only part (one or two) of the first initialization signal lines Vinit1, the second initialization signal lines Vinit2 and the third initialization signal lines Vinit3. The plurality of first initialization signal lines Vinit1, the plurality of second initialization signal lines Vinit2 and the plurality of third initialization signal lines Vinit3 are distributed at intervals in the second direction Y, and each row of pixel circuits 120 is electrically connected to a first initialization signal line Vinit1, a second initialization signal line Vinit2 and a third initialization signal line Vinit3.

In some embodiments, referring to FIGS. 4 and 5, an orthographic projection of the first initialization signal line Vinit1 on the substrate 110 at least partially overlaps with an orthographic projection of the second scan signal line GL2 on the substrate 110, an orthographic projection of the second initialization signal line Vinit2 on the substrate 110 at least partially overlaps with an orthographic projection of the first scan signal line GL1 on the substrate 110, and an orthographic projection of the third initialization signal line Vinit3 on the substrate 110 at least partially overlaps with an orthographic projection of the light emission control signal line EML on the substrate 110. In this way, the second scan signal line GL2 may shield an electric field generated by the first initialization signal line Vinit1, the first scan signal line GL1 may shield an electric field generated by the second initialization signal line Vinit2, and the light emission control signal line EML may shield an electric field generated by the third initialization signal line Vinit3, so that an influence of the first initialization signal line Vinit1, the second initialization signal line Vinit2 and the third initialization signal line Vinit3 on the first semiconductor layer ACT1 and the second semiconductor layer ACT2 may be reduced, thereby reducing an influence on the pixel circuits 120.

In some embodiments, the fourth transistor T4 may be a dual-gate transistor. As shown in FIG. 5, the first wiring layer GT3 may further include a plurality of fourth scan signal line GL4. It can be understood that an orthographic projection of a fourth scan signal line GL4 located in the second gate conductive layer GT2 on the substrate 110 and an orthographic projection of a fourth scan signal line GL4 located in the first wiring layer GT3 on the substrate 110 at least partially overlap, and both transmit the same scan signal. Based on this, both are called the fourth scan signal line GL4.

Referring to FIG. 6, FIG. 6 is a structural diagram of the array substrate 100 with a first source-drain conductive layer SD1 added based on FIG. 5. The first source-drain conductive layer SD1 includes a plurality of source patterns and a plurality of drain patterns, so that a plurality of transistors of the pixel circuits 120 can be electrically connected to the first initialization signal lines Vinit1, the second initialization signal lines Vinit2 and the third initialization signal lines.

Referring to FIGS. 4, 6 and 7, a gate of the first transistor T1 is electrically connected to the first scan signal line GL1, a first electrode of the first transistor T1 is electrically connected to the first initialization signal line Vinit1, and a second electrode of the first transistor T1 is electrically connected to a gate of the driving transistor DT. A gate of the second transistor T2 is electrically connected to the second scan signal line GL2, a first electrode of the second transistor T2 is electrically connected to the second initialization signal line Vinit2, and a second electrode of the second transistor T2 is electrically connected to a first node N1. A gate of the third transistor T3 is electrically connected to the second scan signal line GL2, a first electrode of the third transistor T3 is electrically connected to the third initialization signal line Vinit3, and a second electrode of the third transistor T3 is electrically connected to a first electrode of the driving transistor DT. A gate of the fourth transistor T4 is electrically connected to the third scan signal line GL3, a first electrode of the fourth transistor T4 is electrically connected to a data line DL, and a second electrode of the fourth transistor T4 is electrically connected to the first electrode of the driving transistor DT. A gate of the fifth transistor T5 is electrically connected to the fourth scan signal line GL4, a first electrode of the fifth transistor T5 is electrically connected to a second electrode of the driving transistor TD, and a second electrode of the fifth transistor T5 is electrically connected to the gate of the driving transistor DT. A gate of the sixth transistor T6 is electrically connected to the light emission control signal line EML, a first electrode of the sixth transistor T6 is electrically connected to a first voltage signal line VDD, and a second electrode of the sixth transistor T6 is electrically connected to the first electrode of the driving transistor DT. A gate of the seventh transistor T7 is electrically connected to the light emission control signal line EML, a first electrode of the seventh transistor T7 is electrically connected to a second electrode of the driving transistor DT, and a second electrode of the seventh transistor T7 is electrically connected to the first node N1. A first electrode plate of the capacitor Cst is electrically connected to the first voltage signal line VDD, and a second electrode plate of the capacitor Cst is electrically connected to the gate of the driving transistor DT.

The fifth transistor T5 is an oxide thin film transistor which may reduce the leakage current of the gate of the driving transistor DT, so that the driving transistor DT has a uniform brightness within a display frame. The driving transistor DT, the first transistor T1, the second transistor T2, the third transistor T3, the fourth transistor T4, the sixth transistor T6 and the seventh transistor T7 are low-temperature polysilicon thin film transistors which may enhance a response speed of the pixel circuit 120.

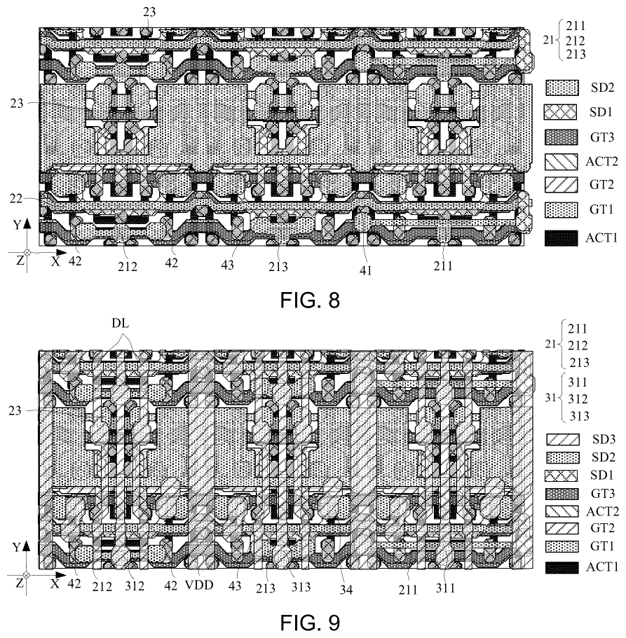

FIG. 8 is a structural diagram of the array substrate 100 with a bridge line layer SD2 added based on FIG. 6. Referring to FIG. 8, the bridge line layer SD2 includes a plurality of transfer blocks 21, a plurality of first fanout lines 22 and a plurality of columns of receiving patterns 23. The plurality of transfer blocks 21 are arranged in a plurality of columns, and each column includes multiple transfer blocks 21 arranged in the second direction Y. The plurality of first fanout lines 22 (each first fanout line 22 in the plurality of first fanout lines 22) extend in the first direction X, and the plurality of first fanout lines 22 are arranged at intervals in the second direction Y.

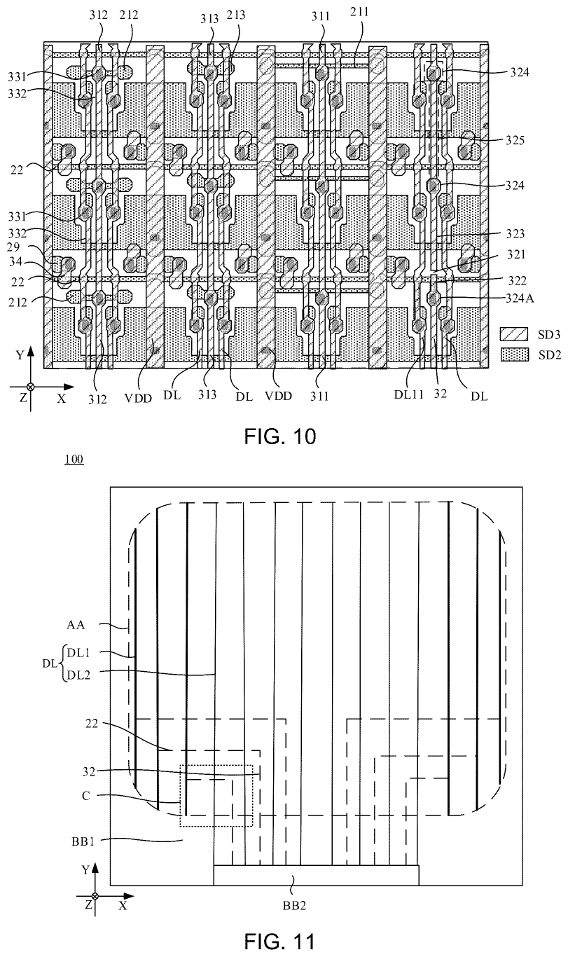

FIG. 9 is a structural diagram of the array substrate 100 with a second wiring layer SD3 added based on FIG. 8. Referring to FIG. 9, the second wiring layer SD3 is disposed on a side of the bridge line layer SD2 away from the substrate 110, and includes a plurality of connecting lines 31 and a plurality of data lines DL extending in the second direction Y. FIG. 10 is a diagram showing a stacked structure of the bridge line layer SD2 and the second wiring layer SD3. Referring to FIG. 10, the second wiring layer SD3 further includes a plurality of second fanout lines 32.

Referring to FIGS. 9 and 10, each connecting line 31 is electrically connected to one of the plurality of first initialization signal lines Vinit1, the plurality of second initialization signal lines Vinit2 and the plurality of third initialization signal lines Vinit3 by multiple transfer blocks 21 in a column, and multiple connecting lines 31 may be electrically connected to at least one of the plurality of first initialization signal lines Vinit1, the plurality of second initialization signal lines Vinit2 and the plurality of third initialization signal lines Vinit3. In this way, the connecting lines 31 may allow the at least one of the plurality of first initialization signal lines Vinit1, the plurality of second initialization signal lines Vinit2 and the plurality of third initialization signal lines Vinit3 to be connected to form a grid structure with horizontal and vertical cross, thereby reducing the power consumption of the array substrate 100 and helping to improve the display quality of the display panel.

For example, each connecting line of all the connecting lines 31 is electrically connected to the plurality of first initialization signal lines Vinit1. Alternatively, each connecting line 31 of all the connecting lines 31 is electrically connected to the plurality of second initialization signal lines Vinit2. Alternatively, each connecting line 31 of all the connecting lines 31 is electrically connected to the plurality of third initialization signal lines Vinit3. Alternatively, of all the connecting lines 31, some connecting lines 31 are electrically connected to the plurality of first initialization signal lines Vinit1, and some connecting lines 31 are electrically connected to the plurality of second initialization signal lines Vinit2. Alternatively, of all the connecting lines 31, some connecting lines 31 are electrically connected to the plurality of first initialization signal lines Vinit1, and some connecting lines 31 are electrically connected to the plurality of third initialization signal lines Vinit3. Alternatively, of all the connecting lines 31, some connecting lines 31 in all the connecting lines 31 are electrically connected to the plurality of second initialization signal lines Vinit2, and some connecting lines 31 are electrically connected to the plurality of third initialization signal lines Vinit3. Alternatively, of all the connecting lines 31, some connecting lines 31 are electrically connected to the plurality of first initialization signal lines Vinit1, some connecting lines 31 are electrically connected to the plurality of second initialization signal lines Vinit2, and some connecting lines 31 are electrically connected to the plurality of third initialization signal lines Vinit3.

For example, the plurality of connecting lines 31 are electrically connected to the plurality of first initialization signal lines Vinit1, and the plurality of connecting lines 31 and the plurality of first initialization signal lines Vinit1 form a grid structure, which is equivalent to connecting the plurality of first initialization signal lines Vinit1 in parallel by the plurality of connecting lines 31. Thus, a resistance of the plurality of first initialization signal lines Vinit1 may be reduced, and a voltage drop generated by a voltage signal during transmission of the voltage signal on the plurality of first initialization signal lines Vinit1 may be reduced, thereby reducing the power consumption of the array substrate 100. Similarly, the plurality of connecting lines 31 may reduce the resistance and the voltage drop of at least one of the plurality of first initialization signal lines Vinit1, the plurality of second initialization signal lines Vinit2 and the plurality of third initialization signal lines Vinit3, thereby reducing the power consumption of the array substrate 100 and helping to improve the display quality of the display panel.

In some embodiments, referring to FIGS. 6 and 9, the connecting line 31 is electrically connected to the first initialization signal line Vinit1, the second initialization signal line Vinit2 or the third initialization signal line Vinit3 by a transfer block 21 in the bridge line layer SD2 and a connection pattern (a first connection pattern 41, a second connection pattern 42 and a third connection pattern 43, referring to the following text for details) in the first source-drain conductive layer SD1 in sequence.

For example, the plurality of connecting lines 31 are electrically connected to the plurality of first initialization signal lines Vinit1; or the plurality of connecting lines 31 are electrically connected to the plurality of second initialization signal lines Vinit2; or the plurality of connecting lines 31 are electrically connected to the plurality of third initialization signal lines Vinit3; or the plurality of connecting lines 31 are electrically connected to the plurality of first initialization signal lines Vinit1 and the plurality of second initialization signal lines Vinit2; or the plurality of connecting lines 31 are electrically connected to the plurality of first initialization signal lines Vinit1 and the plurality of third initialization signal lines Vinit3; or the plurality of connecting lines 31 are electrically connected to the plurality of second initialization signal lines Vinit2 and the plurality of third initialization signal lines Vinit3; or the plurality of connecting lines 31 are electrically connected to the plurality of first initialization signal lines Vinit1, the plurality of second initialization signal lines Vinit2, and the plurality of third initialization signal lines Vinit3.

It can be understood that in the embodiments of the present disclosure, on a basis of the above embodiments, an increase or decrease in the types of initialization signal lines is further included. For example, the array substrate further includes a plurality of fourth initialization signal lines, and the plurality of connecting lines may also be electrically connected to the plurality of fourth initialization signal lines. Alternatively, the array substrate may include only a plurality of first initialization signal lines and a plurality of second initialization signal lines, and the plurality of connecting lines are electrically connected to the plurality of first initialization signal lines and/or the plurality of second initialization signal lines.

As shown in FIG. 9, each data line DL is electrically connected to a column of pixel circuits 120. For example, each data line DL is electrically connected to a column of receiving patterns 23, and multiple receiving patterns 23 in a column are electrically connected to multiple pixel circuits in a column, respectively.

Referring to FIG. 11, the plurality of data lines DL may include a plurality of first data lines DL1 and a plurality of second data lines DL2. The first data lines DL1 are located in the display area AA, that is, the first data lines DL1 do not extend to the fanout area BB1. The second fanout lines 32 extend to the fanout area BB1. A first data line DL1, a first fanout line 22 and a second fanout line 32 are sequentially connected, and the first fanout line 22 is electrically connected to the first data line DL1 and the second fanout line 32. In other words, the first data line DL1 is a data line DL in the array substrate 100 that need to be led out to the fanout area BB1 through the first fanout line 22 and the second fanout line 32 in sequence. The second data lines DL2 extend to the fanout area BB1 directly. Such a provision may be referred to as a Fanout in AA (FIAA) or Fanout in Panel (FIP). This is beneficial to reducing a dimension of the fanout area BB1 in the second direction Y (i.e., reducing a frame width of the array substrate 100), thereby being beneficial to realizing a narrow frame of the display device.

For example, referring to FIG. 11, the data line DL needs to pass through at least part of the fanout area BB1 and extend to a side of the fanout area BB1 away from the display area AA, for example, extend to a bonding area BB2 of the fanout area BB1. The bonding area BB2 may be bonded and connected to a driving circuit board or a driver chip, and thus the driving circuit board or the driver chip is bonded and electrically connected to the data line DL to transmit a data signal to the data line DL, so that the pixel circuit can drive the light-emitting device to emit light.

As shown in FIG. 11, in the first direction X, a dimension of the bonding area BB2 is less than a dimension of the display area AA. In the second direction Y, the bonding area BB2 is disposed opposite to a middle area of the display area AA. The data lines DL located in two side areas of the display area AA in the first direction are first data lines DL1, and the data lines DL located in a middle area of the display area AA in the first direction X are second data lines DL2. For example, in the second direction Y, the second data lines DL2 are disposed opposite to the bonding area BB2, and the first data lines DL1 are located on both sides of the second data lines DL2 in the first direction X. In this way, the first data lines DL1 located on both sides of the bonding area BB2 in the first direction X are each led out by the first fanout line 22 and the second fanout line 32, and the second data lines DL2 disposed opposite to the bonding area BB2 are directly led out, so as to be beneficial to reducing the dimension of the fanout area BB1 in the second direction Y, thereby achieving the narrow frame.

It can be understood that in the array substrate, there may be a plurality of fanout areas BB1 and a plurality of bonding areas BB2. For example, in a large-sized display device (e.g., a television or a computer), the array substrate may include a plurality of fanout areas BB1 and a plurality of bonding areas BB2, the data lines DL disposed opposite to the bonding areas BB2 in the second direction Y may be considered as the second data lines DL2, and the remaining data lines DL may be considered as the first data lines DL1. Of course, a manner of distinguishing the first data lines DL1 and the second data lines DL2 is not limited thereto, and the first data lines DL1 and the second data lines DL2 may be provided in different areas as required.

As described above, in the embodiments provided by the present disclosure, the provision of the bridge line layer SD2 and the second wiring layer SD3 may enable (by the connecting lines 31 and the transfer blocks 21) at least one of the first initialization signal lines Vinit1, the second initialization signal lines Vinit2 and the third initialization signal lines Vinit3 to be connected in parallel to form a grid structure, thereby reducing the power consumption of the array substrate 100, and may enable (by the first fanout lines 22 and the second fanout lines 32) the first data lines DL1 at the edge of the display area AA to be led out from the display area AA, thereby reducing the width (the dimension in the second direction Y) of the fanout area BB1. That is, effects of reducing the resistance of the first initialization signal lines Vinit1, the second initialization signal lines Vinit2 and the third initialization signal lines Vinit3 and reducing the width of the fanout area BB1 may both be achieved.

The following embodiments of the present disclosure will be exemplarily described by considering an example where the plurality of connecting lines 31 are respectively electrically connected to the plurality of first initialization signal lines Vinit1, the plurality of second initialization signal lines Vinit2 and the plurality of third initialization signal lines by the plurality of transfer blocks 21. That is to say, the plurality of connecting lines 31 simultaneously make the plurality of first initialization signal lines Vinit1 electrically connected in parallel, the plurality of second initialization signal lines Vinit2 electrically connected in parallel and the plurality of third initialization signal lines Vinit3 electrically connected in parallel, so as to form three independent grid structures. Any two of the first initialization signal lines Vinit1, the second initialization signal lines Vinit2 and the third initialization signal lines Vinit3 are electrically insulated from each other.

In some embodiments, as shown in FIG. 10, the plurality of connecting lines 31 includes a plurality of first connecting lines 311, a plurality of second connecting lines 312 and a plurality of third connecting lines 313 that are extends in the second direction Y. The plurality of first connecting lines 311, the plurality of second connecting lines 312 and the plurality of third connecting lines 313 are disposed at intervals in the first direction X. The plurality of transfer blocks 21 include a plurality of columns of first transfer blocks 211, a plurality of columns of second transfer blocks 212 and a plurality of columns of third transfer blocks 213 that are disposed at intervals in the first direction X. Each column of first transfer blocks 211 includes multiple first transfer blocks 211 spaced apart in the second direction Y, each column of second transfer blocks 212 includes multiple second transfer blocks 212 spaced apart in the second direction Y, and each column of third transfer blocks 213 includes multiple third transfer blocks 213 spaced apart in the second direction Y. A first connecting line 311 is electrically connected to the plurality (all) of first initialization signal lines Vinit1 by the multiple first transfer blocks 211 in a column, a second connecting line 312 is electrically connected to the plurality (all) of second initialization signal lines Vinit2 by the multiple second transfer blocks 212 in a column, and a third connecting line 313 is electrically connected to the plurality (all) of third initialization signal lines Vinit3 by the multiple third transfer blocks 213 in a column.

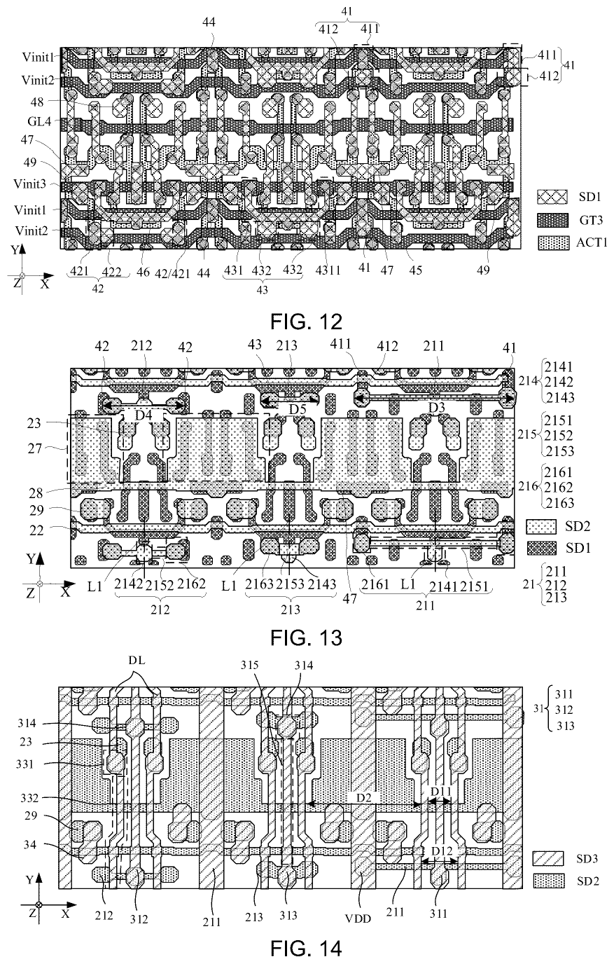

In some embodiments, referring to FIG. 12, the first source-drain conductive layer SD1 includes a plurality of first connection patterns 41, a plurality of second connection patterns 42, a plurality of third connection patterns 43, a plurality of fourth connection patterns 44, a plurality of fifth connection patterns 45 and a plurality of sixth connection patterns 46. It can be understood that in FIG. 12, in order to facilitate identification of the structure of the first source-drain conductive layer SD1 and the connection relationship between the first source-drain conductive layer SD1 and the first wiring layer GT3, the pixel circuits 120 are represented only by the first semiconductor layer ACT1, and other film layers between the first semiconductor layer ACT1 and the first wiring layer GT3 are omitted.

As shown in FIG. 12, the first connection pattern 41 includes a first sub-pattern 411 and a second sub-pattern 412. The first sub-pattern 411 is electrically connected to a first initialization signal line Vinit1 and a pixel circuit 120, respectively. In FIG. 12, the pixel circuits 120 are represented by the first semiconductor layer ACT1. FIG. 13 is a diagram showing a stacked structure of the first source-drain conductive layer SD1 and the bridge line layer SD2. Referring to FIGS. 12 and 13, an orthographic projection of the second sub-pattern 412 on the substrate 110 is located within an orthographic projection of a first transfer block 211 on the substrate 110, and the second sub-pattern 412 is electrically connected to the first transfer block 211.

For example, as shown in FIG. 12, the first connection pattern 41 extends in the second direction Y, the first sub-pattern 411 is closer to the first initialization signal line Vinit1 than the second sub-pattern 412, and in the first direction X, a dimension of the first sub-pattern 411 is less than a dimension of the second sub-pattern 412. In this way, as shown in FIG. 13, it is conducive to increase a facing area between the second sub-pattern 412 and the first transfer block 211, thereby increasing a contact area between the second sub-pattern 412 and the first transfer block 211 and reducing a contact resistance between the second sub-pattern 412 and the first transfer block 211.

For example, as shown in FIG. 13, a first transfer block 211 is electrically connected to two first connection patterns 41. As shown in FIG. 13, the two first connection patterns 41 electrically connected to the same first transfer block 211 are disposed symmetrically.

As shown in FIG. 12, a shape and a size of a fourth connection pattern 44 are respectively the same as a shape and a size of the first sub-pattern 411. The fourth connection pattern 44 is electrically connected to the first initialization signal line Vinit1 and a pixel circuit 120 (the first semiconductor layer ACT1), respectively.

Referring to FIGS. 12 and 13, the fourth connection pattern 44 is a necessary structure for connecting the first initialization signal line Vinit1 and the pixel circuit 120, that is, whether the first connecting line 311 and the first transfer blocks 211 are provided or not, the first source-drain conductive layer SD1 includes the fourth connection pattern 44. The first connection pattern 41 may be considered to be the fourth connection pattern 44 with the second sub-pattern 412 added thereto; in other words, the second sub-pattern 412 is disposed in the first source-drain conductive layer SD1 and the second sub-pattern 412 is connected to the first sub-pattern 411 (the first connection pattern 41). In this way, the second sub-pattern 412 may be connected to the first initialization signal line Vinit1 by the first sub-pattern 411, so as to simplify a structure of the first connection pattern 41 and reduce a structural change of the first source-drain conductive layer SD1 to the greatest extent, thereby being conducive to reduction of the difficulty in forming the first source-drain conductive layer SD1.

In some other embodiments, all or some of the fourth connection patterns 44 in the first source-drain conductive layer SD1 may be replaced by the first connection patterns 41 to improve a pattern consistency of the first source-drain conductive layer SD1. In this case, only some of the first connection patterns 41 are used to be electrically connected to the first transfer blocks 211, and the other of the first connection patterns 41 are only used to connect the first initialization signal line Vinit1 and the pixel circuits 120.

As shown in FIG. 12, the second connection pattern 42 includes a third sub-pattern 421 and a fourth sub-pattern 422. The third sub-pattern 421 is electrically connected to a second initialization signal line Vinit2 and a pixel circuit 120 (the first semiconductor layer ACT1), respectively. As shown in FIG. 13, an orthographic projection of the fourth sub-pattern 422 on the substrate 110 is located within an orthographic projection of a second transfer block 212 on the substrate 110, and the fourth sub-pattern 422 is electrically connected to the second transfer block 212.

For example, as shown in FIG. 13, a second transfer block 212 is electrically connected to two second connection patterns 42. As shown in FIG. 12, the two second connection patterns 42 electrically connected to the same second transfer block 212 are disposed symmetrically. The fourth sub-pattern 422 is connected to an inner side (a side close to a symmetry axis of the two second connection patterns 42) of the third sub-pattern 421, and in the first direction X, a dimension of the fourth sub-pattern 422 is greater than a dimension of the third sub-pattern 421. Thus, a facing area between the fourth sub-pattern 422 and the second transfer block 212 may increase, thereby increasing a contact area between the fourth sub-pattern 422 and the second transfer block 212 and reducing a contact resistance between the fourth sub-pattern 422 and the second transfer block 212.

As shown in FIG. 12, a shape and a size of a fifth connection pattern 45 are respectively the same as a shape and a size of the third sub-pattern 421, that is, the shape of the fifth connection pattern 45 is the same as the shape of the third sub-pattern 421, and the size of the fifth connection pattern 45 is the same as the size of the third sub-pattern 421. The fifth connection pattern 45 is electrically connected to the second initialization signal line Vinit2 and a pixel circuit 120, respectively.

Referring to FIGS. 12 and 13, the fifth connection pattern 45 is a necessary structure for connecting the second initialization signal line Vinit2 and the pixel circuit 120 (the first semiconductor layer ACT1). The second connection pattern 42 may be considered to be the fifth connection pattern 45 with the fourth sub-pattern 422 added thereto. In this way, the fourth sub-pattern 422 may be connected to the second initialization signal line Vinit2 by the third sub-pattern 421, so as to simplify a structure of the second connection pattern 42, thereby being conducive to reduction of a patterning degree of the first source-drain conductive layer SD1 and the reduction of the difficulty in forming the first source-drain conductive layer SD1.

In some other embodiments, all or some of the fifth connection pattern 45 in the first source-drain conductive layer SD1 may be replaced by the second connection patterns 42 to improve the pattern consistency of the first source-drain conductive layer SD1. In this case, only some of the second connection patterns 42 are used to be electrically connected to the second transfer blocks 212, and the other of the second connection patterns 42 are only used to connect the second initialization signal line Vinit2 and the pixel circuits 120.

As shown in FIG. 12, the third connection pattern 43 includes a fifth sub-pattern 431 and sixth sub-patterns 432. The fifth sub-pattern 431 is electrically connected to a third initialization signal line Vinit3 and a pixel circuit 120 (the first semiconductor layer ACT1), respectively. As shown in FIG. 13, an orthographic projection of the sixth sub-pattern 432 on the substrate 110 at least partially overlaps with an orthographic projection of a third transfer block 213 on the substrate 110, and the sixth sub-pattern 432 is electrically connected to the third transfer block 213.

For example, as shown in FIG. 12, the fifth sub-pattern 431 may be an axisymmetric figure, and the fifth sub-pattern 431 is disposed symmetrically about an axis extending in the second direction Y. For example, the fifth sub-pattern 431 substantially has a “C”-shaped structure and includes two first parts 4311, each of orthographic projections of the two first parts 4311 on the substrate 110 at least overlaps with an orthographic projection of the first initialization signal line Vinit1 on the substrate 110, and the two first parts 4311 are each electrically connected to the first initialization signal line Vinit1. The third connection pattern 43 includes two sixth sub-patterns 432, and the two sixth sub-patterns 432 are disposed symmetrically about a symmetry axis of the fifth sub-pattern 431. As shown in FIG. 13, the two sixth sub-patterns 432 are each electrically connected to the third transfer block 213.

As shown in FIG. 12, a shape and a size of a sixth connection pattern 46 are respectively the same as a shape and a size of the fifth sub-pattern 431, that is, the shape of the sixth connection pattern 46 is the same as the shape of the fifth sub-pattern 431, and the size of the sixth connection pattern 46 is the same as the size of the fifth sub-pattern 431. The sixth connection pattern 46 is electrically connected to the third initialization signal line Vinit3 and a pixel circuit 120, respectively.

Referring to FIGS. 12 and 13, the sixth connection pattern 46 is a necessary structure for connecting the third initialization signal line Vinit3 and the pixel circuit 120. The third connection pattern 43 may be considered to be the sixth connection pattern 46 with the sixth sub-pattern 432 added thereto. In this way, the sixth sub-pattern 432 may be connected to the third initialization signal line Vinit3 by the fifth sub-pattern 431, so as to simplify a structure of the third connection pattern 43, thereby being conducive to reduction of the difficulty in forming the first source-drain conductive layer SD1.

In some other embodiments, all or some of the sixth connection patterns 46 in the first source-drain conductive layer SD1 may be replaced by the third connection patterns 43 to improve the pattern consistency of the first source-drain conductive layer SD1. In this case, only some of the third connection patterns 43 are used to be electrically connected to the third transfer blocks 213, and the other of the third connection patterns 43 are only used to connect the third initialization signal line Vinit3 and the pixel circuits 120.

In some embodiments, referring to FIG. 12, the first source-drain conductive layer SD1 further includes seventh connection patterns 47, eighth connection patterns 48 and ninth connection patterns 49. The seventh connection pattern 47 is electrically connected to a pixel circuit (the first semiconductor layer ACT1), and is configured to transmit a first voltage signal (e.g., a power supply voltage signal). The eighth connection pattern 48 is electrically connected to a pixel circuit and is configured to transmit a data signal. The ninth connection pattern 49 is configured to electrically connect a pixel circuit 120 with a light-emitting device.

Referring to FIG. 13, the bridge line layer SD2 includes a plurality of transfer blocks 21, the plurality of transfer blocks 21 are arranged in a plurality of columns, each column includes multiple transfer blocks 21 disposed at intervals in the second direction Y, and multiple transfer blocks 21 in a column are respectively electrically connected to the plurality of first initialization signal lines Vinit1, the plurality of second initialization signal lines Vinit2 or the third initialization signal line Vinit3. Referring to FIG. 14, a connecting line 31 is electrically connected to multiple transfer blocks 21 in a column. In this way, each connecting line 31 may be electrically connected to one of the plurality of first initialization signal lines Vinit1, the plurality of second initialization signal lines Vinit2 or the plurality of third initialization signal lines Vinit3.

For example, as shown in FIG. 13, the plurality of transfer blocks 21 include a plurality of columns of first transfer blocks 211, a plurality of columns of second transfer blocks 212 and a plurality of columns of third transfer blocks 213 that are spaced apart in the first direction X. Each column of first transfer blocks 211 includes multiple first transfer blocks 211 disposed at intervals in the second direction Y, each column of second transfer blocks 212 includes multiple second transfer blocks 212 disposed at intervals in the second direction Y, and each column of third transfer blocks 213 includes multiple third transfer blocks 213 disposed at intervals in the second direction Y. FIG. 13 only exemplarily shows a column of first transfer blocks 211, a column of second transfer blocks 212 and a column of third transfer blocks 213, and a column of first transfer blocks 211 exemplarily shows only two first transfer blocks 211 spaced apart in the second direction Y.

For example, as shown in FIG. 14, the plurality of connecting lines 31 include a plurality of first connecting lines 311, a plurality of second connecting lines 312 and a plurality of third connecting lines 313. A first connecting line 311 is electrically connected to the plurality of (all) first initialization signal lines Vinit1 by the multiple (all) first transfer blocks 211 in a column, a second connecting line 312 is electrically connected to the plurality of (all) second initialization signal lines Vinit2 by the multiple (all) second transfer blocks 212 in a column, and a third connecting line 313 is electrically connected to the plurality of (all) third initialization signal lines Vinit3 by the multiple (all) third transfer blocks 213 in a column. FIG. 14 only exemplarily shows a first connecting line 311, a second connecting line 312 and a third connecting line 313.

As shown in FIG. 13, two ends of at least one transfer block 21 in the first direction X are both electrically connected to the first initialization signal line Vinit1, the second initialization signal line Vinit2 or the third initialization signal line Vinit3. In this way, even if a connection between an end of the transfer block 21 and an initialization signal line (the first initialization signal line Vinit1, the second initialization signal line Vinit2 or the third initialization signal line Vinit3) fails, the other end of the transfer block 21 may still be electrically connected to the initialization signal line, thereby being beneficial to increasing the connection reliability between the transfer block 21 and the initialization signal line.

For example, two ends of each transfer block in the plurality of columns of first transfer blocks 211 in the first direction X are each electrically connected to the first initialization signal line Vinit1; two ends of each transfer block in the plurality of columns of second transfer blocks 212 in the first direction X are each electrically connected to the second initialization signal line Vinit2; and two ends of each transfer block in the plurality of columns of third transfer blocks 213 in the first direction X are each electrically connected to the third initialization signal line Vinit3. This is beneficial to increasing the connection reliability between the transfer block 21 and the initialization signal line.

In some embodiments, referring to FIGS. 13 and 14, at least one transfer block 21 is disposed symmetrically about a connecting line 31 electrically connected to the transfer block 21. This is beneficial for uniform transmission of a signal on both sides of a first sub-portion 214. The transfer block 21 may include a first sub-portion 214, second sub-portion(s) 215 and third sub-portion(s) 216.

An orthographic projection of the first sub-portion 214 on the substrate 110 partially overlaps with an orthographic projection of the connecting line 31 on the substrate 110. For example, an orthographic projection of the first sub-portion 214 on the substrate 110 is located within an orthographic projection of the connecting line 31 on the substrate 110. The first sub-portion 214 is electrically connected to the connecting line 31. The second sub-portion 215 extends in the first direction X and is connected to the first sub-portion 214, and the second sub-portion 215 is disposed symmetrically about a midline L1 of the first sub-portion 214 in the first direction X. The midline L1 of the first sub-portion 214 in the first direction X refers to a line for connecting midpoints of the first sub-portion 214 in the first direction. As shown in FIG. 14, the midline L1 of the first sub-portion 214 in the first direction X extends in the second direction Y, and the first sub-portion 214 is symmetrical about the midline L1.

The third sub-portions 216 are connected to both ends of the second sub-portion 215 in the first direction X. In the second direction Y, a dimension of the third sub-portion 216 is greater than a dimension of the second sub-portion 215. The third sub-portion 216 is electrically connected to the first initialization signal line Vinit1 (by the first connection pattern 41). Alternatively, the third sub-portion 216 is electrically connected to the second initialization signal line Vinit2 (by the second connection pattern 42). Alternatively, the third sub-portion 216 is electrically connected to the third initialization signal line Vinit3 (by the third connection pattern 43). A dimension of the third sub-portion 216 in the second direction Y is greater than a dimension of the second sub-portion 215 in the second direction Y, which facilitates a contact between the third sub-portion 216 and the first connection pattern 41, the second connection pattern 42 or the third connection patterns 43.

For example, in a case where the transfer block 21 is disposed symmetrically about the connecting line 31 electrically connected to the transfer block 21, the second sub-portion 215 of the transfer block 21 is disposed symmetrically about the midline L1 of the first sub-portion 214 in the first direction X, the transfer block 21 includes two third sub-portions 216, and the two third sub-portions 216 are respectively connected to the two ends of the second sub-portion 215 in the first direction X.

For example, referring to FIGS. 13 and 14, the first transfer block 211 is disposed symmetrically about the first connecting line 311 electrically connected to the first transfer block 211. The first transfer block 211 includes a first transfer portion 2141, a second transfer portion 2151 and third transfer portions 2161. An orthographic projection of the first transfer portion 2141 on the substrate 110 coincides with an orthographic projection of the first connecting line 311 on the substrate 110, and the first connecting line 311 is electrically connected to the first transfer portion 2141.

With continued reference to FIG. 13, the second transfer portion 2151 extends in the first direction X, and the second transfer portion 2151 is connected to an end (an upper end) of the first transfer portion 2141 in the second direction Y. The second transfer portion 2151 is symmetrically disposed about a midline L11 of the first transfer portion 2141 in the first direction X. That is, the second transfer portion 2151 is located on a side of the first transfer portion 2141 in the second direction Y.

The two third transfer portions 2161 are connected to two ends of the second transfer portion 2151 in the first direction X, respectively. The third transfer portion 2161 is electrically connected to the first initialization signal line Vinit1 by a first connection pattern 41. For example, the third transfer portion 2161 is electrically connected to the second sub-pattern 412 of the first connection pattern 41 in the first source-drain conductive layer SD1, and is electrically connected to the first initialization signal line Vinit1 by the first sub-pattern 411 of the first connection pattern 41.

In the second direction Y, a dimension of the third transfer portion 2161 is greater than a dimension of the second transfer portion 2151. This is beneficial to increasing a facing area between the third transfer portion 2161 and the first connection pattern 41, thereby increasing a contact area between the third transfer portion 2161 and the first connection pattern 41 and reducing a contact resistance between the third transfer portion 2161 and the first connection pattern 41.

For example, as shown in FIG. 14, the second transfer block 212 is disposed symmetrically about the second connecting line 312 electrically connected to the second transfer block 212. As shown in FIG. 13, the second transfer block 212 includes a fourth transfer portion 2142, two fifth transfer portions 2152 and two sixth transfer portions 2162. As shown in FIG. 14, an orthographic projection of the fourth transfer portion 2142 on the substrate 110 coincides with an orthographic projection of the second connecting line 312 on the substrate 110, and the fourth transfer portion 2142 is electrically connected to the second connecting line 312.

As shown in FIG. 13, the two fifth transfer portions 2152 are respectively connected to two ends of the fourth transfer portion 2142 in the first direction X, and are disposed symmetrically about the fourth transfer portion 2142. That is, the two fifth transfer portions 2152 are arranged at intervals in the first direction X, and the fourth transfer portion 2142 is located between the two fifth transfer portions 2152 and connected to the two fifth transfer portions 2152. In the second direction Y, a dimension of the fourth transfer portion 2142 is greater than a dimension of the fifth transfer portion 2152. This is beneficial to increasing a facing area between the fourth transfer portion 2142 and the second connecting line 312, thereby increasing a contact area between the fourth transfer portion 2142 and the second connecting line 312 and reducing a contact resistance between the fourth transfer portion 2142 and the second connecting line 312.

The two sixth transfer portions 2162 are respectively connected to ends of the two fifth transfer portions 2152 away from the fourth transfer portion 2142. The sixth transfer portion 2162 is electrically connected to the second initialization signal line Vinit2 by a second connection pattern 42. For example, each sixth transfer portion 2162 is electrically connected to the fourth sub-pattern 422 of the second connection pattern 42 in the first source-drain conductive layer SD1, and is electrically connected to the second initialization signal line Vinit2 by the third sub-pattern 421 of the second connection pattern 42.

In the second direction Y, a dimension of the sixth transfer portion 2162 is greater than a dimension of the fifth transfer portion 2152. This is beneficial to increasing a facing area between the sixth transfer portion 2162 and the second connection pattern 42, thereby increasing a contact area between the sixth transfer portion 2162 and the second connection pattern 42 and reducing a contact resistance between the sixth transfer portion 2162 and the second connection pattern 42.

For example, as shown in FIG. 14, the third transfer block 213 is disposed symmetrically about the third connecting line 313 electrically connected to the third transfer block 213. The third transfer block 213 includes a seventh transfer portion 2143, an eighth transfer portion 2153 and two ninth transfer portions 2163. An orthographic projection of the seventh transfer portion 2143 on the substrate 110 coincides with an orthographic projection of the third connecting line 313 on the substrate 110, and the seventh transfer portion 2143 is electrically connected to the third connecting line 313.

Referring to FIG. 13, the eighth transfer portion 2153 extends in the first direction X and is connected to an end of the seventh transfer portion 2143 in the second direction Y, and is disposed symmetrically about a midline of the seventh transfer portion 2143 in the first direction X. The third connecting line 313 is electrically connected to the seventh transfer portion 2143 and the eighth transfer portion 2153.

The two ninth transfer portions 2163 are each connected to an end of the eighth transfer portion 2153 away from the seventh transfer portion 2143. The ninth transfer portion 2163 is electrically connected to the third initialization signal line Vinit3. For example, as shown in FIGS. 12 and 13, the ninth transfer portion 2163 is electrically connected to the sixth sub-pattern 432 of the third connection pattern 43 in the first source-drain conductive layer SD1, and is electrically connected to the third initialization signal line Vinit3 by the fifth sub-pattern 431 of the third connection pattern 43.

In the second direction Y, a dimension of the ninth transfer portion 2163 is greater than a dimension of the eighth transfer portion 2153. This is beneficial to increasing a contact area between the ninth transfer portion 2163 and the third connection pattern 43, thereby reducing a contact resistance between the ninth transfer portion 2163 and the third connection pattern 43.

In some embodiments, as shown in FIG. 13, the first transfer block 211, the second transfer block 212 and the third transfer block 213 are arranged in the first direction X, that is, the first transfer block 211, the second transfer block 212 and the third transfer block 213 are arranged side by side in the first direction X. This is beneficial to improving a space utilization rate of the bridge line layer SD2 and facilitating provision of other structures (e.g., the first fanout line 22, a shielding pattern 27 and a first signal transfer line 28) in the bridge line layer SD2.

In some embodiments, referring to FIG. 13, in the first direction X, an interval between two first connection patterns 41 connected to the same first transfer block 211 is greater than an interval between two second connection patterns 42 connected to the same second transfer block 212, and the interval between the two second connection patterns 42 connected to the same second transfer block 212 is greater than an interval between two sixth sub-patterns 432 of the third connection pattern 43 connected to the same third transfer block 213. Based on this, as shown in FIG. 13, in the first direction X, a dimension D3 of the first transfer block 211 is greater than a dimension D4 of the second transfer block 212, and the dimension D4 of the second transfer block 212 is greater than a dimension D5 of the third transfer block 213.

In some embodiments, in the first direction X, the first transfer block 211, the second transfer block 212 and the third transfer block 213, as a whole, are arranged repeatedly. That is to say, the adjacent units, each composed of the first transfer block 211, the second transfer block 212 and the third transfer block 213, are arranged in the same order. For example, in the first direction X, the second transfer block 212, the third transfer block 213, the first transfer block 211, the second transfer block 212, the third transfer block 213, the first transfer block 211, . . . are arranged in sequence. The present disclosure does not limit the arrangement order of the first transfer block 211, the second transfer block 212 and the third transfer block 213.

In the first direction X, the first transfer block 211, the second transfer block 212 and the third transfer block 213, as a whole, are arranged repeatedly. Thus, in the first direction X, every two adjacent first transfer blocks 211 have an equal interval therebetween, every two adjacent second transfer blocks 212 have an equal interval therebetween, and every two adjacent third transfer blocks 213 have an equal interval therebetween. This is beneficial to improving the uniformity of the grid structure formed by the first initialization signal lines Vinit1 and the first connecting lines 311, improving the uniformity of the grid structure formed by the second initialization signal lines Vinit2 and the second connecting lines 312, and improving the uniformity of the grid structure formed by the third initialization signal lines Vinit3 and the third connecting lines 313. Therefore, the first initialization signal lines Vinit1, the second initialization signal lines Vinit2, and the third initialization signal lines Vinit3 have the uniform and equal resistances.

Corresponding to the repeated arrangement of the first transfer block 211, the second transfer block 212 and the third transfer block 213, the first connecting line 311, the second connecting line 312 and the third connecting line 313, as a whole, are also arranged repeatedly. The arrangement order of the first connecting line 311, the second connecting line 312 and the third connecting line 313 are correspondingly the same as the arrangement order of the first transfer block 211, the second transfer block 212 and the third transfer block 213.

As shown in FIG. 13, the bridge line layer SD2 further includes a plurality of first fanout lines 22. The plurality of first fanout lines 22 are arranged at intervals in the second direction Y, and each first fanout line 22 extends in the first direction X. For example, both ends of the first fanout line 22 in the first direction X may extend to an edge of the display area AA to improve the pattern uniformity of the bridge line layer SD2. Of course, the first fanout line 22 may be provided with openings (e.g., a second opening 221 and a third opening 222) to divide the first fanout line 22 into multiple segments.

In the second direction Y, the first fanout line 22 and the plurality of transfer blocks 21 are provided in a staggered manner. That is, in the second direction Y, there is a gap between the first fanout line 22 and the transfer block 21. This is beneficial to reducing signal interference between the first fanout line 22 and the transfer block 21 and avoiding a contact between the first fanout line 22 and the transfer block 21.

In some embodiments, as shown in FIG. 13, the bridge line layer SD2 further includes a plurality of shielding patterns 27, and an orthographic projection of a shielding pattern 27 on the substrate 110 cover an orthographic projection of a pixel circuit 120 on the substrate 110. The shielding pattern 27 may shield interference of the pixel circuit 120 by the signal line (e.g., the data line DL) in the second wiring layer SD3.

In some embodiments, as shown in FIG. 13, the bridge line layer SD2 further includes a plurality of first signal transfer lines 28. The plurality of first signal transfer lines 28 are disposed at intervals in the second direction Y, and each first signal transfer line 28 extends in the first direction. A first signal transfer line 28 is connected to a row of shielding patterns 27, and the shielding patterns 27 may reduce the resistance of the first signal transfer line 28. As shown in FIG. 13, the first signal transfer line 28 is electrically connected to the seventh connection pattern 47 in the first source-drain conductive layer SD1 and is electrically connected to the pixel circuit through the seventh connection pattern 47 to transmit the first voltage signal to the seventh connection pattern 47 and the pixel circuit.

In some embodiments, as shown in FIG. 13, in the second direction Y, at least a portion of the first transfer block 211 is disposed opposite to a shielding pattern 27. For example, two edges of the first transfer block 211 in the first direction are respectively opposite to two adjacent shielding patterns 27. In the second direction Y, at least a portion of the second transfer block 212 is disposed opposite to a shielding pattern 27. For example, two edges of second transfer block 212 in the first direction are respectively opposite to two adjacent shielding patterns 27. In the first direction X, the third transfer block 213 is staggered with the shielding pattern 27, that is, in the second direction Y, the third transfer block 213 has no portion opposite to the shielding pattern 27.

In some embodiments, as shown in FIG. 13, the bridge line layer SD2 further includes a plurality of tenth connection patterns 29, and the tenth connection pattern 29 is electrically connected to a ninth connection pattern 49 to electrically connect the pixel circuit 120 to the light-emitting device 200.

As shown in FIG. 14, the second wiring layer SD3 includes a plurality of data lines DL. The plurality of data lines DL are divided into a plurality of groups, and each group includes two adjacent data lines DL. Two data lines DL in a group have a first interval D1 therebetween, and two adjacent groups of data lines DL have a second interval D2 therebetween. The first interval D1 is less than the second interval D2. In other words, two data lines DL that are close to each other belong to a group. For example, the data line DL is a broken line. As shown in FIG. 14, two data lines DL in a group includes a first sub-interval D11 and a second sub-interval D12 therebetween. In the first direction X, a dimension of the first sub-interval D11 is greater than a dimension of the second sub-interval D12, and the dimension of the first sub-interval D11 is less than that of the second interval D2 between two adjacent groups of data lines DL.

With continued reference to FIG. 14, the data line DL includes third widened portions 331 and third extending portion 332 that are disposed alternately (alternately connected) in the second direction Y. That is, two adjacent third widened portions 331 are connected by a third extending portion 332, and two adjacent third extending portions 332 are connected by a third widened portion 331.

An orthographic projection of the third widened portion 331 on the substrate 110 partially overlaps with an orthographic projection of a receiving pattern 23 on the substrate 110. The third widened portion 331 is used to be electrically connected to the receiving pattern 23. A dimension of the third widened portion 331 in the first direction X is greater than a dimension of the third extending portion 332 in the first direction X. This is beneficial to increasing a facing area between the third widened portion 331 and the receiving pattern 23, thereby increasing a contact area between the third widened portion 331 and the receiving pattern 23 and increasing the connection reliability and stability between the third widened portion 331 and the receiving pattern 23.

As shown in FIG. 14, the second wiring layer SD3 further includes a plurality of connecting lines 31. For example, the second wiring layer SD3 includes a first connecting line 311, a second connecting line 312 and a third connecting line 313. The connecting line 31 includes second widened portions 314 and second extending portions 315 that are disposed alternately (alternately connected) in the second direction Y. That is, two adjacent second widened portions 314 are connected by a second extending portion 315, and two adjacent second extending portions 315 are connected by a second widened portion 314.

An orthographic projection of the second widened portion 314 on the substrate 110 overlaps with an orthographic projection of a transfer block 21 on the substrate 110. The second widened portion 314 is used to be electrically connected to the transfer block 21. A dimension of the second widened portion 314 in the first direction X is greater than a dimension of the second extending portion 315 in the first direction X. This is beneficial to increasing a facing area between the second widened portion 314 and the transfer block 21, thereby increasing a contact area between the second widened portion 314 and the transfer block 21 and increasing the connection reliability and stability between the second widened portion 314 and the transfer block 21.

As shown in FIG. 14, in the second direction Y, the third widened portion 331 and the second widened portion 314 are staggered; that is, in the second direction Y, the third widened portion 331 and the second widened portion 314 have an interval therebetween; in other words, the third widened portion 331 and the second widened portion 314 are not on a straight line extending in the first direction X. This is beneficial to increasing the interval between the third widened portion 331 and the second widened portion 314, that is, beneficial to increasing an interval between the data line and the connecting line 31, thereby reducing a risk of signal interference between the data line DL and the connecting line 31.

As shown in FIG. 14, each connecting line 31 is located between two data lines DL in a group, and the two data lines DL in a group are disposed symmetrically about the middle data line 31. This is beneficial to improving the space utilization rate of the second wiring layer SD3, improving the wiring density of the data lines DL and the connecting lines 31, and further improving the pixels per inch (PPI) of the display panel. For example, the second widened portion 314 is located in the second sub-interval D12 between the two data lines DL in a group.

In some embodiments, as shown in FIG. 14, the second wiring layer SD3 further includes a plurality of first voltage signal lines VDD, the first voltage signal lines VDD extends in the second direction Y, and the plurality of first voltage signal lines VDD are disposed at intervals in the first direction X. An orthographic projection of a first voltage signal line VDD on the substrate 110 partially overlaps with an orthographic projection of a first signal transfer lines 28 in the bridge line layer SD2 on the substrate 110, and each first voltage signal line VDD is electrically connected to the plurality of (all) first signal transfer lines 28. That is, the first voltage signal line VDD is electrically connected to the first signal transfer line 28, the seventh connection pattern 47 and the pixel circuit in sequence. The plurality of first voltage signal lines VDD and the plurality of first signal transfer lines 28 are interconnected to form a grid structure, which is beneficial to reducing the resistances of the first voltage signal lines VDD and the plurality of first signal transfer lines 28.

For example, as shown in FIG. 14, a first voltage signal line VDD is included between each two adjacent groups of data lines DL. The first voltage signal line VDD is used, for example, to transmit a power supply voltage signal. In the first direction X, a width of the first voltage signal line VDD is greater than a width of the data line DL and greater than a width of the connecting line 31.

As shown in FIG. 14, the second wiring layer SD3 further includes a plurality of eleventh connection patterns 34. An orthographic projection of an eleventh connection pattern 34 on the substrate 110 overlaps with an orthographic projection of a tenth connection pattern 29 in the bridge line layer SD2 on the substrate 110, and the eleventh connection pattern 34 is electrically connected to the tenth connection pattern 29. That is, the eleventh connection pattern 34 is electrically connected to the tenth connection pattern 29, the ninth connection pattern and the pixel circuit in sequence.

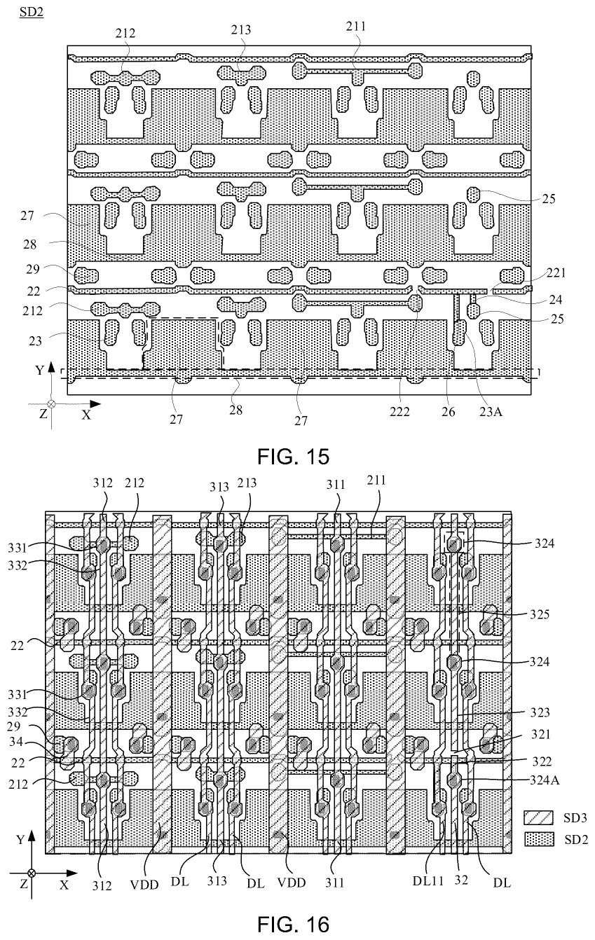

In some embodiments, referring to FIG. 15, the bridge line layer SD2 further includes a first connection segment 24 and connection blocks 25. An end of the first connection segment 24 is connected to the first fanout line 22, and the other end thereof is connected to a connection block 25. Each first connection segment 24 is only connected to a first fanout line 22 and a connection block 25. The connection block 25 is used to be electrically connected to the second fanout line 32. As shown in FIG. 15, in the first direction X, a dimension of the connection block 25 is greater than a width of the first connection segment 24. This is beneficial to increasing a facing area between the connection block 25 and the second fanout line 32, thereby increasing a contact area between the connection block 25 and the second fanout line 32 and reducing a contact resistance between the connection block 25 and the second fanout line 32.

As shown in FIG. 15, in multiple connection blocks 25 in a column, only one connection block 25 is electrically connected to the first fanout line 22 by a first connection segment 24, so that a second fanout line 32 may be electrically connected to the only first fanout line 22. Forming the multiple connection blocks 25 in a column is beneficial to improving the pattern uniformity of the bridge line layer SD2.

Referring to FIG. 16, the second wiring layer SD3 further includes a second fanout line 32. In some embodiments, a structure of the second fanout line 32 is the same as a structure of the connecting line 31, so as to improve the pattern uniformity of the second wiring layer SD3 and reduce the difficulty of forming the second wiring layer SD3.

As shown in FIG. 16, the second fanout line 32 includes a plurality of first widened portions 324 and a plurality of first extending portions 325 that are disposed alternately (alternately connected) in the second direction Y.

The first widened portion 324 and the second widened portion 314 of the connecting line 31 are arranged in the first direction X; in other words, the first widened portion 324 and the second widened portion 314 are arranged side by side in the first direction X, so that a shape and a structure of the second fanout line 32 are substantially the same as a shape and a structure of the connecting line 31. This is beneficial to improving the pattern uniformity of the second wiring layer SD3 and reducing the difficulty of forming the second wiring layer SD3.

The first widened portion 324 and the first fanout line 22 are staggered in the second direction Y, that is, an orthographic projection of the first widened portion 324 on the substrate 110 does not overlap with an orthographic projection of the first fanout line 22 on the substrate 110. That is, in the second direction Y, there is a gap between the first widened portion 324 and the first fanout line 22.

The orthographic projection of the first widened portion 324 on the substrate 110 overlaps with an orthographic projection of the connection block 25 on the substrate 110, and the first widened portion 324 is electrically connected to the connection block 25. In the first direction X, a dimension of the first widened portion 324 is greater than a dimension of the first extending portion 325. This is beneficial to increasing a contact area between the first widened portion 324 and the connection block 25, thereby increasing the connection stability between the first widened portion 324 and the connection block 25.

As shown in FIG. 16, similar to the connecting line 31, each second fanout line 32 is also located between two data lines DL in a group. For example, the first widened portion 324 of the second fanout line 32 may also be located in the second sub-interval D12 between the two data lines DL. This is beneficial to improving the space utilization rate of the second wiring layer SD3, improving the wiring density of the data lines DL, the connecting lines 31 and the second fanout lines 32, and further improving the PPI of the display panel.

In some embodiments, as shown in FIG. 16, the second fanout line 32 passes through the display area AA in the second direction Y. That is, in the display area AA, a length of the second fanout line 32 in the second direction Y is substantially the same as a length of the connecting line 31 in the second direction Y. Moreover, in the display area AA, the shape and the structure of the second fanout line 32 are substantially the same as the shape and the structure of the connecting line 31. This is beneficial to improving the pattern uniformity of the second wiring layer SD3 and reducing the difficulty of forming the second wiring layer SD3.

As shown in FIG. 16, the second fanout line 32 further includes a first opening 321, and the first opening 321 divides the second fanout line 32 into a first routing segment 322 and a second routing segment 323. An end (e.g., a lower end) of the first routing segment 322 extends to the fanout area BB1 (not shown in the figure), and the other end thereof extends to a first fanout line 22 electrically connected to the second fanout line 32 and is electrically connected to the first fanout line 22. The second routing segment 323 is located on a side of the first routing segment 322 away from the fanout area BB1, and the second routing segment 323 is electrically insulated from the first routing segment.

The first opening 321 divides the second fanout line 32 into the first routing segment 322 and the second routing segment 323 that are electrically insulated from each other. The first fanout line 22 is electrically connected to the first routing segment 322 and extends to the fanout area BB1 through the first routing segment 322. For example, the second routing segment 323 may also be used to transmit another signal. For example, the array substrate 100 further includes a second voltage signal line VSS located in the peripheral area BB and at least partially surrounding the display area AA. The second voltage signal line VSS may be, for example, electrically connected to a cathode layer of the light-emitting device. The second routing segment 323 may be electrically connected to the second voltage signal line VSS and electrically connected to the cathode layer. That is, the second routing segment 323 and the cathode layer are provided in parallel. This is beneficial to reducing the resistance of the cathode layer and beneficial to shortening a transmission path of a data signal on the second fanout line 32, thereby reducing the voltage drop of the data signal during transmission on the second fanout line 32.

The plurality of first widened portions 324 include a target first widened portion 324A. The target first widened portion 324A is a first widened portion 324 closest to the first fanout line 22 in the plurality of first widened portions 324 of the first routing segment 322. The first connection segment 24 connects the first fanout line 22 and the target first widened portion 324A. In this way, the first routing segment 322 is electrically connected to the first fanout line 22 by the target first widened portion 324A and the first connection segment 24 in sequence, and thus there is no need to provide a widened area in the first routing segment 322 directly above the first fanout line 22, which is conducive to simplifying the structure of the first routing segment 322 and improving the uniformity of the second wiring layer SD3.

With continued reference to FIG. 15, the bridge line layer SD2 further includes a second connection segment 26 and a plurality of columns of receiving patterns 23. Each column of the plurality of columns of receiving patterns 23 includes multiple receiving patterns 23 disposed at intervals in the second direction Y. Multiple receiving patterns 23 in a column are respectively electrically connected to multiple pixel circuits (not shown in the figure) in a column, and the multiple receiving patterns 23 in a column are also electrically connected to a data line DL. For example, the data line DL is electrically connected to the multiple receiving patterns 23 in a column, multiple eighth connection patterns 48 in a column, and the multiple pixel circuits in a column in sequence, thereby transmitting the data signal transmitted by the data line DL to the pixel circuits. That is, the multiple receiving patterns 23 in a column are respectively electrically connected to the multiple eighth connection patterns 48 in a column in the first source-drain conductive layer SD, and are electrically connected to the multiple pixel circuits in a column by the multiple eighth connection patterns 48 in a column.

As shown in FIG. 15, an end of the second connection segment 26 is electrically connected to the first fanout line 22, and the other end thereof is connected to a target receiving pattern 23. The target receiving pattern 23A is a receiving pattern 23, located on a side of the first fanout line 22 proximate to the fanout area BB1 and closest to the first fanout line 22, in the receiving patterns 23 in a column electrically connected to the first data line DL1. It can be understood that a first fanout line 22 is electrically connected to a receiving pattern 23 only by a second connection segment 26.

That is, the first data line DL1 is electrically connected to the target receiving pattern 23A, the second connection segment 26, the first fanout line 22, the first connection segment 24, the connection block 25 and the second fanout line 32 in sequence. Moreover, the first data line DL1 is also electrically connected to the target receiving pattern 23A, the eighth connection pattern 48 and the pixel circuit in sequence. In this way, there is no need to provide a connection structure between the first data line DL1 and the first fanout line 22 (e.g., there is no need to additionally provide a via hole in the second planarization layer), which is conducive to simplifying the connection structure between the first data line DL1 and the first fanout line 22.

As shown in FIG. 15, the first fanout line 22 further includes a second opening 221. The second opening 221 is located on a side of the first connection segment 24 away from the first data line DL1 electrically connected to the first fanout line 22. The second opening 221 divides the first fanout line 22 into two segments, thereby shortening the transmission path of the data signal on the first fanout line 22 and reducing the voltage drop of the data signal on the first fanout line 22.

As shown in FIG. 16, an orthogonal projection of the second opening 221 on the substrate 110 overlaps with an orthographic projection of a data line DL closest to the first connection segment 24 on the substrate 110. In this way, the transmission path of the data signal on the first fanout line 22 may be shortened to the greatest extent, and the second opening 221 may be prevented from disconnecting the first connection segment 24, thereby improving the stability of the signal transmission from the first connection segment 24 to the first fanout line 22.

As shown in FIG. 15, the first fanout line 22 further includes a third opening 222. The third opening 222 is located on a side of the first data line DL1 electrically connected to the first fanout line 22 away from the second fanout line 32 electrically connected to the first fanout line 22. In other words, the third opening 222 is located on a side of the second connection segment 26 away from the second fanout line 32. The third opening 222 divides the first fanout line 22 into two segments, thereby further shortening the transmission path of the data signal on the first fanout line 22 and reducing the voltage drop of the data signal on the first fanout line 22.

As shown in FIG. 16, an orthogonal projection of the third opening 222 on the substrate 110 overlaps with an orthographic projection of a connecting line 31 or a first voltage signal line VDD (the first voltage signal line VDD in FIG. 16) closest to the second connection segment 26 on the substrate 110. In this way, the transmission path of the data signal on the first fanout line 22 may be shortened to the greatest extent, and the third opening 222 may be prevented from disconnecting the second connection segment 26, thereby improving the stability of the signal transmission from the second connection segment 26 to the first fanout line 22.

For example, the first fanout line 22 includes both a second opening 221 and a third opening 222, and a portion of the first fanout line 22 between the second opening 221 and the third opening 222 is used to transmit a data signal. In this way, the transmission path of the data signal on the first fanout line 22 may be shortened to the greatest extent, and the loss of the data signal on the first fanout line 22 may be reduced. Of course, in some other embodiments, the first fanout line 22 may include only one of the second opening 221 and the third opening 222, and details are not repeated here.

In some embodiments, referring to FIGS. 15 and 16, the plurality of first data lines DL1 include at least one first data sub-line DL11. An orthographic projection of a first data sub-line DL11 on the substrate 110 does not overlap with an orthographic projection of a transfer block 21 on the substrate 110. An orthographic projection of a second connection segment 26 electrically connected to the first data sub-line DL11 on the substrate 110 is located within an orthographic projection of the first data sub-line DL11 on the substrate 110. In this way, the second connection segment 26 electrically connected to the first data sub-line DL11 will not interfere with the transfer block 21; in other words, there is no transfer block 21 between a receiving pattern 23 electrically connected to the first data sub-line DL11 and a first fanout line 22 electrically connected to the first data sub-line DL11.

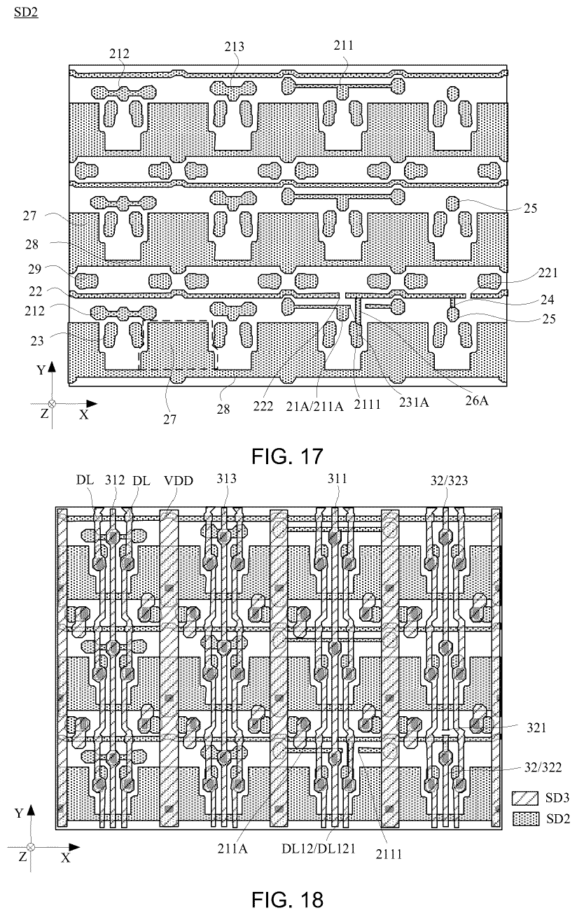

In some embodiments, referring to FIGS. 17 to 24, the plurality of first data lines DL1 further include at least one second data sub-line DL12. An orthographic projection of a second data sub-line DL12 on the substrate 110 partially overlaps with an orthographic projection of a column of transfer blocks 21 on the substrate 110.

A column of transfer blocks 21 electrically connected to the second data sub-line DL12 includes a target transfer block 21A, and the target transfer block 21A is located on a side of a first fanout line 22 electrically connected to the second data sub-line DL12 proximate to the fanout area BB1 and is closest to the first fanout line 22 electrically connected to the second data sub-line DL12. An orthographic projection of the target transfer block 21A on the substrate 110 does not overlap with an orthographic projection of the second data sub-line DL12 on the substrate 110. For example, in the plurality of transfer blocks 21, orthographic projections of all transfer blocks 21 except the target transfer block 21A on the substrate 110 each partially overlap with an orthographic projections of a connecting line 31 electrically connected to the transfer block 21 on the substrate 110, and all the transfer blocks 21 except the target transfer block 21A are disposed symmetrically about the connecting line 31 electrically connected to the transfer block 21.

A second connection segment 26 electrically connected to the second data sub-line DL12 is a target connection segment 26A. An orthographic projection of the target connection segment 26A on the substrate 110 is located within the orthographic projection of the second data sub-line DL12 on the substrate 110, and the target connection segment 26A extends in the second direction Y and has an interval from the target transfer block 21A. And/or, the target connection segment 26A is a broken line, the orthographic projection of the target connection segment 26A on the substrate 110 does not at least partially overlap with the orthographic projection of the second data sub-line DL12 on the substrate 110, and there is a gap between the target connection segment 26A and the target transfer block 21A.

In some embodiments, referring to FIGS. 17 and 18, at least one second data sub-line DL12 includes a first target data line DL121, and an orthographic projection of the first target data line DL121 on the substrate 110 partially overlaps with an orthographic projection of a column of first transfer blocks 211 on the substrate 110.

As shown in FIG. 17, a receiving pattern for connecting the first target data line DL121 and the first fanout line 22 is a first target receiving pattern 231A. In the second direction Y, at least a portion of the first transfer block 211 is disposed opposite to a shielding pattern 27. For example, two ends of the first transfer block 211 in the first direction X are disposed opposite to the shielding pattern 27. The target transfer blocks 21A include a first target transfer block 211A. A first transfer block 211 is included between the first target receiving pattern 231A and the first fanout line 22. The first transfer block 211 is a first target transfer block 211A.

In other words, as shown in FIG. 17, multiple first transfer blocks 211, electrically connected to the second data sub-line DL12, in a column include a first target transfer block 211A, and the first target transfer block 211A is located between the first fanout line 22 electrically connected to the first target data line DL121 and the first target receiving pattern 231A.

As shown in FIG. 17, the first target transfer block 211A has a fourth opening 2111, and a target connection segment 26A electrically connected to the first target data line DL121 extends in the second direction Y. The target connection segment 26A passes through the fourth opening 2111, and the target connection segment 26A and the first target transfer block 211A have an avoidance gap therebetween. In this way, the first target transfer block 211A is provided with the fourth opening 2111 therein, and the fourth opening 2111 is used to avoid the target connection segment 26A electrically connected to the first target data line DL121, so as to avoid a short circuit between the first target transfer block 211A and the target connection segment 26A, thereby ensuring that the data signal and the first initialization signal will not interfere with each other.

In some embodiments, as shown in FIG. 18, an orthographic projection of the target connection segment 26A electrically connected to the first target data line DL121 on the substrate 110 is located within the orthographic projection of the first target data line DL121 on the substrate 110.

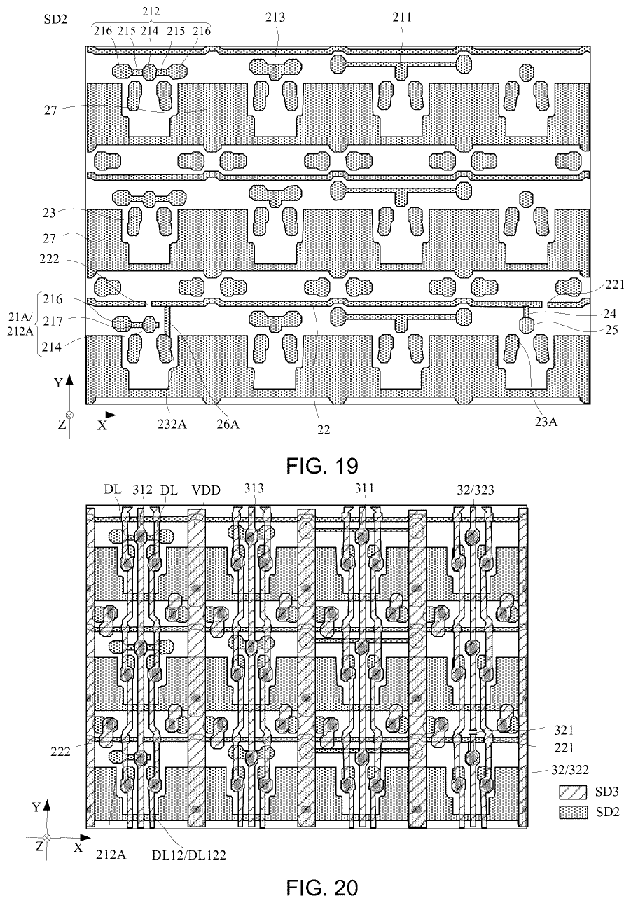

In some embodiments, as shown in FIGS. 19 and 20, at least one second data sub-line DL12 includes a second target data line DL122, and an orthographic projection of the second target data line DL122 on the substrate 110 partially overlaps with an orthographic projection of a column of second transfer blocks 212 on the substrate 110.

As shown in FIG. 19, a target receiving pattern 23A further includes a second target receiving pattern 232A. The second target receiving pattern 232A is used to connect the second target data line DL122 and the first fanout line 22. The target transfer blocks 21A include a second target transfer block (also called a target second transfer block) 212A. Multiple second transfer blocks 212, electrically connected to the second target data line DL122, in a column include a target second transfer block 212A. In the second direction Y, the target second transfer block 212A is located between the first fanout line 22 electrically connected to the second target data line DL122 and the second target receiving pattern 232A.

In the second direction Y, at least a portion of the second transfer block 212 is disposed opposite to a shielding pattern 27. For example, two ends of the second transfer block 212 in the first direction X are disposed opposite to the shielding pattern 27. That is, a second transfer block 212 is included between the second target receiving pattern 232A and the first fanout line 22, and the second transfer block 212 is a target second transfer block 212A.

In other words, as shown in FIG. 19, multiple second transfer blocks 212, electrically connected to the second target data line DL122, in a column include a second target transfer block 212A, and the second target transfer block 212A is located between the first fanout line 22 electrically connected to the second target data line DL122 and the second target receiving pattern 232A.

For example, an orthographic projection of the second target data line DL122 on the substrate 110 partially overlaps with orthographic projections of all second transfer blocks 212 in a column of the second transfer blocks 212 except the target second transfer block 212A on the substrate 110.

As shown in FIG. 19, the other second transfer blocks 212 except the target second transfer block 212A include a first sub-portion 214, a second sub-portion 215 and two third sub-portions 216. The two third sub-portions 216 are located on opposite sides of the first sub-portion 214 in the first direction X, and the second sub-portion 215 connects the first sub-portion 214 and the two third sub-portions 216.

As shown in FIG. 19, a target connection segment 26A electrically connected to the second target data line DL122 extends in the second direction Y. As shown in FIG. 20, an orthographic projection of the target connection segment 26A on the substrate 110 is located within an orthographic projection of a third data sub-line on the substrate 110.

As shown in FIG. 19, the target second transfer block 212A includes a first sub-portion 214, a fourth sub-portion 217 and a third sub-portion 216. The third sub-portion 216 is located on a side of the first sub-portion 214 away from the target connection segment 26A. The fourth sub-portion 217 is located between the first sub-portion 214 and the third sub-portion 216 and connects the first sub-portion 214 and the third sub-portion 216. That is, compared with other second transfer blocks 212, the target second transfer block 212A removes a third sub-portion 216 proximate to the target connection segment 26A and removes a portion of the second sub-portion 215 used to connect the first sub-portion 214 and the third sub-portion 216 at the right side (a side proximate to the target connection segment 26A). Removing a portion of the target second transfer block 212A proximate to the target connection segment 26A (compared with other second transfer blocks 212) may avoid a short circuit between the target second transfer block 212A and the target connection segment 26A, thereby ensuring that the data signal and the second initialization signal will not interfere with each other. In another embodiment of the present disclosure, the target connection segment 26A may be designed as a broken line or a curve shape, so that the third sub-portion 216 is half-enclosed within the target broken line or curved connection segment 26A without removing a portion of the third sub-portion 216.

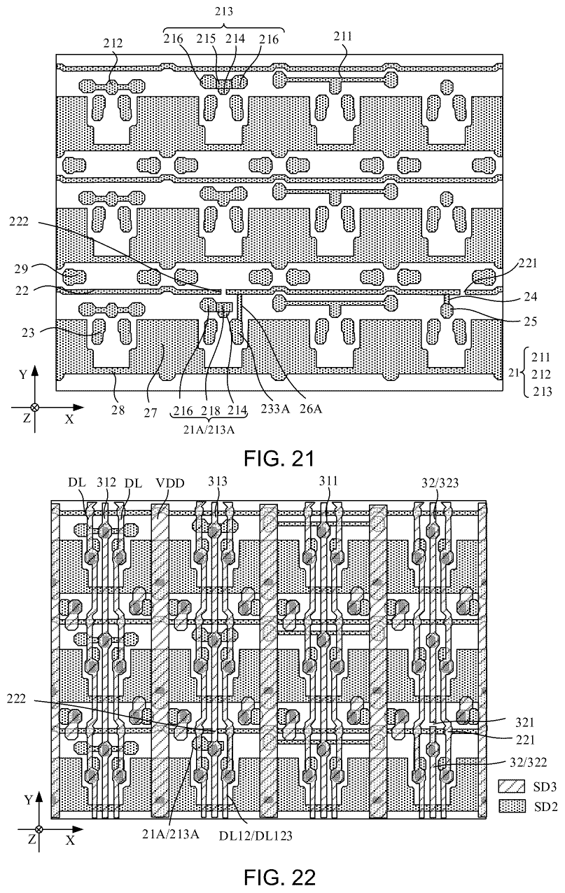

In some embodiments, as shown in FIGS. 21 and 22, the plurality of first data lines DL1 include at least one third target data line DL123, and an orthographic projection of a third target data line DL123 on the substrate 110 partially overlaps with an orthographic projection of a column of third transfer blocks 213 on the substrate 110.

As shown in FIG. 21, the target receiving pattern 23A further includes a third target receiving pattern 233A. The third target receiving pattern 233A is used to connect the third target data line DL123 and the first fanout line 22. The target transfer blocks 21A further include a third target transfer block (also called a target third transfer block) 213A. A column of third transfer blocks 213 electrically connected to the third target data line DL123 includes a target third transfer block 213A. In the second direction Y, the target third transfer block 213A is located between the first fanout line 22 electrically connected to the second data sub-line DL12 and the third target receiving pattern 233A.

As shown in FIG. 21, in the first direction X, the third transfer block 213 is staggered with the shielding pattern 27, that is, in the second direction Y, the third transfer block 213 has no portion opposite to the shielding pattern 27. In this way, there may be a wiring space between the third transfer block 213 and the shielding pattern 27.

For example, an orthographic projection of the third target data line DL123 on the substrate 110 partially overlaps with orthographic projections of all third transfer blocks 213 in a column of third transfer blocks 213 except the target third transfer block 213A on the substrate 110.

In some embodiments, as shown in FIGS. 21 and 22, a target connection segment 26A electrically connected to the third target data line DL123 extends in the second direction Y. An orthographic projection of the second connection segment 26 electrically connected to the third target data line DL123 on the substrate 110 is located within an orthographic projection of the third target data line DL123 on the substrate 110.

As shown in FIG. 21, the other third transfer blocks 213 except the target third transfer block 213A include a first sub-portion 214, a second sub-portion 215 and two third sub-portions 216. The two third sub-portions 216 are located on opposite sides of the first sub-portion 214 in the first direction X, and the second sub-portion 215 connects the first sub-portion 214 and the two third sub-portions 216.

Referring to FIG. 21, the target third transfer block 213A includes a first sub-portion 214, a fifth sub-portion 218 and a third sub-portion 216. The third sub-portion 216 is located on a side of the first sub-portion 214 away from the target connection segment 26A. The fifth sub-portion 218 is located between the first sub-portion 214 and the third sub-portion 216 and connects the first sub-portion 214 and the third sub-portion 216. In other words, compared with other third transfer blocks 213, the target third transfer block 213A removes a third sub-portion 216 proximate to the target connection segment 26A and removes a portion of the fifth sub-portion 218 used to connect the first sub-portion 214 and the third sub-portion 216 at the right side (a side proximate to the target connection segment 26A). That is, removing a portion of the target third transfer block 213A proximate to the target connection segment 26A (compared with other third transfer blocks 213) may avoid a short circuit between the target third transfer block 213A and the target connection segment 26A, thereby ensuring that the data signal and the third initialization signal will not interfere with each other.

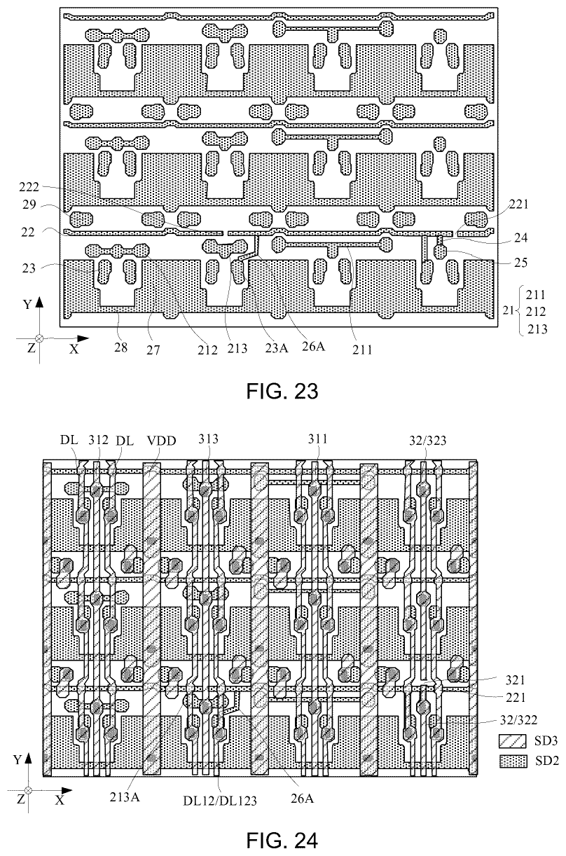

In some other embodiments, as shown in FIGS. 23 and 24, a second connection segment 26 electrically connected to the third target data line DL123 is a target connection segment 26A, the target connection segment 26A is a broken line segment, and the target connection segment 26A and the third transfer block 213 have a gap therebetween. An orthographic projection of the target connection segment 26A on the substrate 110 does not at least partially overlap with an orthographic projection of the third target data line DL123 on the substrate 110.

As shown in FIG. 23, in the first direction X, the third transfer block 213 is staggered with the shielding pattern 27, that is, in the second direction Y, the third transfer block 213 has no portion opposite to the shielding pattern 27. In this way, there may be a wiring space between the third transfer block 213 and the shielding pattern 27. The target connection segment 26A electrically connected to the third target data line DL123 is located in the wiring space.

In some embodiments, there may be 1 to 10 connecting lines 31 between two adjacent second fanout lines 32. For example, there is 1, 3, 6 or 10 connecting lines between two adjacent second fanout lines 32, which is not limited in the embodiments of the present disclosure.

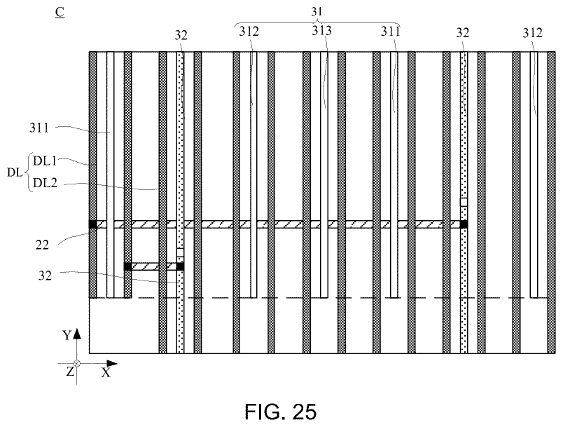

For example, as shown in FIG. 25, three connecting lines 31 are included between two adjacent second fanout lines 32, and the three connecting lines 31 are respectively a first connecting line 311, a second connecting line 312, and a third connecting line 313. In some embodiments, the first connecting lines 311, the second connecting lines 312, and the third connecting lines 313 have equal wiring densities.

In some embodiments, three adjacent connecting lines 31 include a first connecting line 311, a second connecting line 312 and a third connecting line 313, and an arrangement order of the first connecting line 311, the second connecting line 312 and the third connecting line 313 that are adjacent may be selected optionally.

In some embodiments, three connecting lines 31 are included between two adjacent second fanout lines 32, and the three connecting lines 31 are respectively a first connecting line 311, a second connecting line 312, and a third connecting line 313.

For example, between two adjacent second fanout lines 32, in the first direction X and in a direction from an edge of the display area AA to another edge thereof (e.g., from left to right), the second connecting line 312, the third connecting line 313 and the first connecting line 311 are disposed sequentially. Alternatively, between two adjacent second fanout lines 32, in the first direction X and in a direction from an edge of the display area AA to another edge thereof (e.g., from left to right), the second connecting line 312, the first connecting line 311 and the third connecting line 313 are disposed sequentially. Alternatively, between two adjacent second fanout lines 32, in the first direction X and in a direction from an edge of the display area AA to another edge thereof (e.g., from left to right), the first connecting line 311, the second connecting line 312 and the third connecting line 313 are disposed sequentially. Alternatively, between two adjacent second fanout lines 32, in the first direction X and in a direction from an edge of the display area AA to another edge thereof (e.g., from left to right), the first connecting line 311, the third connecting line 313 and the second connecting line 312 are disposed sequentially. Alternatively, between two adjacent second fanout lines 32, in the first direction X and in a direction from an edge of the display area AA to another edge thereof (e.g., from left to right), the third connecting line 313, the second connecting line 312 and the first connecting line 311 are disposed sequentially. Alternatively, between two adjacent second fanout lines 32, in the first direction X and in a direction from an edge of the display area AA to another edge thereof (e.g., from left to right), the third connecting line 313, the first connecting line 311 and the second connecting line 312 are disposed sequentially.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. An array substrate having a display area and a fanout area, the fanout area being adjacent to a side edge of the display area; and the array substrate comprising:
a substrate;
a plurality of pixel circuits disposed on the substrate, wherein the plurality of pixel circuits are arranged in a plurality of rows and a plurality of columns;
a first wiring layer disposed on a side of the plurality of pixel circuits away from the substrate and including a plurality of first initialization signal lines, a plurality of second initialization signal lines and a plurality of third initialization signal lines extending in a first direction, wherein the first direction is a row direction in which the plurality of pixel circuits are arranged; each row of pixel circuits is electrically connected to a first initialization signal line, a second initialization signal line and a third initialization signal line;
a bridge line layer disposed on a side of the first wiring layer away from the substrate and including a plurality of columns of transfer blocks and a plurality of first fanout lines, wherein each column of transfer blocks includes multiple transfer blocks disposed at intervals in a second direction, the plurality of first fanout lines extend in the first direction, and the second direction is a column direction in which the plurality of pixel circuits are arranged; and
a second wiring layer disposed on a side of the bridge line layer away from the substrate and including a plurality of connecting lines, a plurality of data lines and a plurality of second fanout lines extending in the second direction, wherein each connecting line is electrically connected to one of the plurality of first initialization signal lines, the plurality of second initialization signal lines and the plurality of third initialization signal lines by a column of transfer blocks; each data line is electrically connected to a column of pixel circuits, the plurality of data lines include a plurality of first data lines, and ends of the first data lines proximate to the fanout area are located in the display area; ends of the second fanout lines proximate to the fanout area extend to the fanout area; and a first fanout line is electrically connected to a first data line and a second fanout line.

2. The array substrate according to claim 1, wherein two ends of at least one transfer block in the first direction are both electrically connected to the first initialization signal line, the second initialization signal line or the third initialization signal line.

3. The array substrate according to claim 2, wherein the at least one transfer block is disposed symmetrically about a connecting line electrically connected to the transfer block, and the transfer block includes:
a first sub-portion, wherein an orthographic projection of the first sub-portion on the substrate partially overlaps with an orthographic projection of the connecting line on the substrate; and the first sub-portion is electrically connected to the connecting line;
a second sub-portion, wherein the second sub-portion extends in the first direction, is connected to the first sub-portion, and is disposed symmetrically about a midline of the first sub-portion in the first direction; and
third sub-portions each connected to an end of the second sub-portion away from the first sub-portion, wherein in the second direction, a dimension of the third sub-portion is greater than a dimension of the second sub-portion; and the third sub-portions are electrically connected to the first initialization signal line, the second initialization signal line or the third initialization signal line.

4. The array substrate according to claim 1, wherein
a plurality of transfer blocks arranged into the plurality of columns of transfer blocks include a plurality of columns of first transfer blocks, a plurality of columns of second transfer blocks and a plurality of columns of third transfer blocks disposed at intervals in the first direction; each column of first transfer blocks includes multiple first transfer blocks disposed at intervals in the second direction, and multiple first transfer blocks in a column are respectively electrically connected to the plurality of first initialization signal lines; each column of second transfer blocks includes multiple second transfer blocks disposed at intervals in the second direction, and multiple second transfer blocks in a column are respectively electrically connected to the plurality of second initialization signal lines; each column of third transfer blocks includes multiple third transfer blocks disposed at intervals in the second direction, and multiple third transfer blocks in a column are respectively electrically connected to the plurality of third initialization signal lines; and
the plurality of connecting lines include a plurality of first connecting lines, a plurality of second connecting lines and a plurality of third connecting lines; a first connecting line is electrically connected to a column of first transfer blocks, a second connecting line is electrically connected to a column of second transfer blocks, and a third connecting line is electrically connected to a column of third transfer blocks.

5. The array substrate according to claim 4, wherein
in the first direction, a dimension of a first transfer block is greater than a dimension of a second transfer block, and the dimension of the second transfer block is greater than a dimension of a third transfer block; and/or
in the first direction, a first transfer block, a second transfer block and a third transfer block, as a whole, are arranged repeatedly, and a first connecting line, a second connecting line and a third connecting line, as a whole , are arranged repeatedly.

6. (canceled)

7. The array substrate according to claim 4, further comprising:
a first source-drain conductive layer disposed between the first wiring layer and the bridge line layer and including a plurality of first connection patterns, a plurality of second connection patterns and a plurality of third connection patterns, wherein
a first connection pattern includes a first sub-pattern and a second sub-pattern; the first sub-pattern is electrically connected to a first initialization signal line and a pixel circuit, and the second sub-pattern is electrically connected to a first transfer block;
a second connection pattern includes a third sub-pattern and a fourth sub-pattern; the third sub-pattern is electrically connected to a second initialization signal line and a pixel circuit, and the fourth sub-pattern is electrically connected to a second transfer block;
a third connection pattern includes a fifth sub-pattern and a sixth sub-pattern; the fifth sub-pattern is electrically connected to a third initialization signal line and a pixel circuit, and the sixth sub-pattern is electrically connected to a third transfer block.

8. The array substrate according to claim 7, wherein the first source-drain conductive layer further includes:
a fourth connection pattern, wherein a shape and a size of the fourth connection pattern are respectively same as a shape and a size of the first sub-pattern, and the fourth connection pattern is electrically connected to the first initialization signal line and a pixel circuit;
a fifth connection pattern, wherein a shape and a size of the fifth connection pattern are respectively same as a shape and a size of the third sub-pattern, and the fifth connection pattern is electrically connected to the second initialization signal line and a pixel circuit; and
a sixth connection pattern, wherein a shape and a size of the sixth connection pattern are respectively same as a shape and a size of the fifth sub-pattern, and the sixth connection pattern is electrically connected to the third initialization signal line and a pixel circuit.

9. The array substrate according to claim 1, wherein the second fanout line includes a first opening, and the first opening divides the second fanout line into a first routing segment and a second routing segment;
an end of the first routing segment extends to the fanout area, and another end of the first routing segment extends to the first fanout line and is electrically connected to the first fanout line; and
the second routing segment is located on a side of the first routing segment away from the fanout area, and is electrically insulated from the first routing segment.

10. The array substrate according to claim 9, wherein the second fanout line further includes a plurality of first widened portions and a plurality of first extended portions that are disposed alternately in the second direction; the first widened portions and the first fanout lines are disposed in a staggered manner in the second direction; and
the bridge line layer further includes a first connection segment, an end of the first connection segment is connected to the first fanout line, and another end of the first connection segment is electrically connected to a first widened portion of the first routing segment closest to the first fanout line.

11. The array substrate according to claim 10, wherein the connecting line includes a plurality of second widened portions and a plurality of second extending portions that are disposed alternately in the second direction; and in the first direction, a dimension of a second widened portion is greater than a dimension of a second extending portion, and the second widened portion is electrically connected to a transfer block; and/or
the first fanout line includes a second opening and a third opening; the second opening is located on a side of the first connect from the first data line electrically connected to the first fanout line, and an orthogonal projection of the second opening on the substrate partially overlaps with an orthographic projection of a data line on the substrate; the third opening is located on a side of the first data line electrically connected to the first fanout line away. from the second fanout line electrically connected to the first fanout line, and an orthogonal projection of the third opening on the substrate partially overlaps with an orthographic projection of a connecting line on the substrate.

12. (canceled)

13. The array substrate according to claim 9, wherein the bridge line layer further includes:
a plurality of columns of receiving patterns each including multiple receiving patterns disposed at intervals in the second direction, wherein multiple receiving patterns in a column are respectively electrically connected to multiple pixel circuits in a column, and the multiple receiving patterns in the column are further electrically connected to a data line; and
a second connection segment, wherein an end of the second connection segment is electrically connected to the first fanout line, and another end of the second connection segment is electrically connected to a target receiving pattern; the target receiving pattern is a receiving pattern located on a side of the first fanout line proximate to the fanout area and closest to the first fanout line.

14. The array substrate according to claim 13, wherein in the second direction, the multiple receiving patterns and the multiple transfer blocks are disposed in a staggered manner, and at least one transfer block is located between the first fanout line and the target receiving pattern.

15. The array substrate according to claim 13, wherein
the plurality of first data lines include at least one first data sub-line, an orthographic projection of the first data sub-line on the substrate does not overlap with an orthographic projection of a transfer block on the substrate; and
an orthographic projection of the second connection segment electrically connected to the first data sub-line on the substrate is located within the orthographic projection of the first data sub-line on the substrate.

16. The array substrate according to claim 13, wherein
the plurality of first data lines include at least one second data sub-line, an orthographic projection of the second data sub-line on the substrate partially overlaps with an orthographic projection of the column of transfer blocks on the substrate;
the column of transfer blocks electrically connected to the second data sub-line includes a target transfer block, the target transfer block is located on a side of the first fanout line proximate to the fanout area and closest to the first fanout line; an orthographic projection of the target transfer block on the substrate does not overlap with the orthographic projection of the second data sub-line on the substrate; and
the second connection segment electrically connected to the second data sub-line is a target connection segment; wherein an orthographic projection of the target connection segment on the substrate is located within the orthographic projection of the second data sub-line on the substrate, and the target connection segment extends in the second direction and is spaced apart from the target transfer block; and/or the target connection segment is a broken line, the orthographic projection of the target connection segment on the substrate does not at least partially overlap with the orthographic projection of the second data sub-line on the substrate, and the target connection segment and the target transfer block have a gap therebetween.

17. The array substrate according to claim 1, wherein two adjacent columns of pixel circuits are disposed symmetrically;
the plurality of data lines are divided into a plurality of groups of data lines, each group of data lines includes two data lines, the two data lines in the group of data lines have a first interval therebetween, two adjacent groups of data lines have a second interval therebetween, and the first interval is less than the second interval; and
each connecting line is located between two data lines in a group of data lines, and the two data lines in the group of data lines are disposed symmetrically about the connecting line;
and each second fanout line is located between two data lines in a group of data lines, and the two data lines in the group of data lines are disposed symmetrically about the second fanout line.

18. The array substrate according to claim 17, wherein 1 to 10 connecting lines are included between two adjacent second fanout lines.

19. The array substrate according to claim 17, wherein the plurality of connecting lines include plurality of first connecting lines, a plurality of second connecting lines and a plurality of third connecting lines, and a first connecting line, a second connecting line and a third connecting line are included in two adjacent second fanout lines, wherein
in the first direction and in a direction from an edge of the display area to another edge thereof, the second connecting line, the third connecting line and the first connecting line are disposed in sequence between two adjacent second fanout lines; or
in the first direction and in a direction from an edge of the display area to another edge thereof, the second connecting line, the first connecting line and the third connecting line are disposed in sequence between two adjacent second fanout lines; or
in the first direction and in a direction from an edge of the display area to another edge thereof, the first connecting line, the second connecting line and the third connecting line are disposed in sequence between two adjacent second fanout lines; or
in the first direction and in a direction from an edge of the display area to another edge thereof, the first connecting line, the third connecting line and the second connecting line are disposed in sequence between two adjacent second fanout lines; or
in the first direction and in a direction from an edge of the display area to another edge thereof, the third connecting line, the second connecting line and the first connecting line are disposed in sequence between two adjacent second fanout lines; or
in the first direction and in a direction from an edge of the display area to another edge thereof, the third connecting line, the first connecting line and the second connecting line are disposed in sequence between two adjacent second fanout lines.

20. The array substrate according to claim 17, wherein
the second wiring layer further includes a plurality of first voltage signal lines disposed at intervals in the first direction, each first voltage signal line extends in the second direction; and a group of data lines is included between two adjacent first voltage signal lines;
the bridge line layer further includes a plurality of first signal transfer lines disposed at intervals in the second direction, and each first signal transfer line extends in the first direction and is electrically connected to a row of pixel circuits; and
each first voltage signal line is electrically connected to the plurality of first voltage signal transfer lines.

21. A display panel, comprising:
the array substrate according to claim 1; and
a plurality of light-emitting devices located on a side of the array substrate, a light-emitting device being electrically connected to a pixel circuit.

22. A display device, comprising:
the display panel according to claim 21; and
a driving circuit board electrically connected to the fanout area of the array substrate and configured to transmit a control signal to the array substrate.
